(19) United States
(12) Patent Application Publication
(10) Pub. No.: US 2014/0029890 A1
(43) Pub. Date: Jan. 30, 2014

(54) OPTICAL SYSTEM WITH INTEGRATED PHOTODETECTORS

(71) Applicants: Xiaochen Sun, Pomona, CA (US); Dawei Zheng, Irvine, CA (US); Ningning Feng, Arcadia, CA (US)

(72) Inventors: Xiaochen Sun, Pomona, CA (US); Dawei Zheng, Irvine, CA (US); Ningning Feng, Arcadia, CA (US)

(73) Assignee: LaXense, Inc., Walnut, CA (US)

(21) Appl. No.: 13/558,240

(22) Filed: Jul. 25, 2012

(51) Int. Cl. G02B 6/12; H01L 33/58

(52) U.S. Cl. 385/14; 438/24; 257/E33.068

(57) ABSTRACT

An optical system and a method of fabrication are provided. The optical system includes a substrate and at least one hole extending from a second side of the substrate towards a first side of the substrate and configured to receive at least one optical fiber. The substrate includes at least one photodetector at the first side or between the at least one hole and the first side and configured to be in an optical path of an optical signal emitted from the at least one optical fiber or transmitted through the first side to the at least one optical fiber. The at least one photodetector is responsive to the optical signal by generating an electrical signal indicative of an intensity of the optical signal

### BACKGROUND

1. Field of the Invention

The present application relates generally to optical micro-assemblies, and more particularly, to systems and methods for coupling light between a fiber array and an array of optical devices, with integrated photodetectors.

2. Description of the Related Art

Optoelectronic systems used for communications usually consist of an optical transmitter and an optical receiver. The optical transmitter usually consists of a plurality of light emitting devices, a plurality of light coupling elements (such as lenses, mirrors, gratings) and a plurality of fibers used to carry light signals along a distance. The receiver usually consists of a plurality of photodetectors, a plurality of light coupling elements, and a plurality of fibers. For relatively short-distance data communication applications, the light emitting devices are usually surface-emitting lasers and the photodetectors are usually surface-receiving photodetectors.

The traditional way of assembling these lasers or photodetectors with optical fibers includes placing a single laser or a single detector in a so-called transistor outline (“TO”) base and affixing a cap having a lens window and a single optical fiber onto the TO base using passive or active alignment to form a whole TO package. A transmitter TO package also includes a mirror structure to deflect some laser light and a monitor photodetector to detect the deflected light for real-time laser power monitoring during practical operations. This well-established assembling and packaging method is limited in that the TO package is only able to contain a single photodetector, or a single laser and a monitor photodetector.

Increasing demands for data transmission bandwidth requires multiple-channel transmitters, receivers, or combined transceivers within a single package for higher density of total bandwidth per volume. A number of standard transceiver packages have been established by the industry, e.g. quad small form-factor pluggable plus (QSFP+) for four-channel transceivers, C form-factor pluggable (CFP) for ten-channel transceivers. These packages and corresponding transceivers have been widely adopted in today's servers, switches, and routers for applications from telecommunications, metro and fiber-to-the-home to supercomputers and datacenters. These multiple-channel transceivers, however, cannot include multiple traditional TO sub-packages due to the large size of these traditional TO sub-packages. Therefore, many approaches have previously been developed for assembling a plurality of lasers (and monitor photodetectors), photodetectors, and fibers into a single and small platform, which is sometimes called an optical engine, and placing the platform inside the standard multi-channel transceiver packages along with other electronic chips.

Some of these configurations use an active alignment approach, similar to that adopted in edge-emitting optoelectronics assemblies, in which a laser or a photodetector is electrically connected to external testing equipment and is actively monitored while a fiber is aligned and attached to the assembly. However, passive alignment assembling processes, in which the fibers are aligned and attached to lasers or photodetectors without active adjustment, can advantageously be used with higher throughputs and lower costs than active alignment procedures. Examples of such prior passive alignment processes include: using a molded plastic fixture with a plurality of lenses and a reflector to hold a fiber and to focus the light in or out of the fiber; using an etched v-groove trench to hold a fiber and an etched reflector to reflect the light between vertical direction (e.g., from a laser or to a photodetector) and a horizontal direction (e.g., to or from a fiber); and using a through-substrate hole to hold a fiber and bonding a laser or a photodetector facing the fiber facet on the substrate.

### SUMMARY

An optical system is provided. The optical system comprises a substrate comprising a first side and a second side facing generally opposite to the first side. The optical system further comprises at least one hole extending from the second side towards the first side. The at least one hole is configured to receive at least one optical fiber. The substrate comprises at least one photodetector at the first side or between the at least one hole and the first side. The at least one photodetector is configured to be in an optical path of an optical signal emitted from the at least one optical fiber or transmitted through the first side to the at least one optical fiber. The at least one photodetector is responsive to the optical signal by generating an electrical signal indicative of an intensity of the optical signal.

The at least one photodetector can comprise a semiconductor material in the optical path. The substrate can comprise an etch stop layer between the at least one hole and the semiconductor material. For example, the semiconductor material can comprise crystalline silicon or polysilicon, and the etch stop layer can comprise silicon oxide. In other examples, the substrate comprises gallium arsenide and the semiconductor material can comprise lattice-matched gallium indium phosphide on the gallium arsenide, or the substrate comprises indium phosphide and the semiconductor material can comprise lattice-matched indium gallium arsenide on the indium phosphide.

The at least one photodetector can comprise a light-responsive diode in the optical path. For example, the light-responsive diode can comprise a p-i-n diode or a p-n diode configured to generate an, electric current in response to the optical signal. The light-responsive diode can comprise a p-doped region, an n-doped region, and a region sandwiched between the p-doped region and the n-doped region. The substrate can further comprise at least one metal layer at the first side, the at least one metal layer configured to be in electrical communication with at least one optical component mounted on the first side. The substrate can further comprise at least one electrically insulative layer between the at least one metal layer and the at least one hole.

An optical system is provided. The optical system comprises a substrate comprising a first side and a second side facing generally opposite to the first side, and at least one hole extending from the second side towards the first side. The optical system further comprises at least one optical fiber mounted to the substrate with a portion of the at least one optical fiber within the at least one hole. The substrate comprises at least one photodetector at the first side or between the at least one optical fiber and the first side. The at least one photodetector is configured to be in an optical path of an optical signal emitted from the at least one optical fiber or transmitted through the first side to the at least one optical fiber. The at least one photodetector is responsive to the optical signal by generating an electrical signal indicative of an intensity of the optical signal.

The at least one hole can comprise an array of holes, the at least one optical fiber can comprise an array of optical fibers, and the at least one photodetector can comprise an array of photodetectors. The optical system can further comprise at least one optical component mounted on the first side with the at least one optical component in optical communication with the at least one optical fiber. The optical path can extend through the first side and between the at least one optical component and the at least one optical fiber. For example, the at least one optical component can comprise a surface emitting light source.

The substrate can further comprise a plurality of metal traces at the first side. The plurality of metal traces can be configured to be flip-chip-bonded to the at least one optical component and to provide electrical communication to the at least one optical component. The substrate can further comprise at least one electrically insulative layer between the plurality of metal traces and the at least one hole. The substrate can further comprise a plurality of metal traces at the first side and in electrical communication with the at least one photodetector.

The optical system can further comprise at least one concave reflective element on the first side and configured to reflect at least a portion of the optical signal emitted from the at least one optical fiber back to the at least one photodetector. The optical system can further comprise at least one ball lens within the at least one hole and between the at least one optical fiber and the at least one photodetector.

A method of fabricating an optical system is provided. The method comprises providing a substrate comprising a first side and a second side facing generally opposite to the first side. The method further comprises forming at least one hole extending from the second side towards the first side, the at least one hole configured to receive at least one optical fiber. The method further comprises forming at least one photodetector. The at least one photodetector is at the first side or between the at least one hole and the first side. The at least one photodetector is configured to be in an optical path of an optical signal emitted from the at least one optical fiber or transmitted through the first side to the at least one optical fiber. The at least one photodetector is responsive to the optical signal by generating an electrical signal indicative of an intensity of the optical signal.

The substrate can comprise an etch stop layer between the first side and the second side, and forming the at least one hole can comprise etching the substrate from the second side towards the first side, wherein the etching terminates at the etch stop layer.

Forming the at least one photodetector can comprise forming a light-responsive diode in the optical path. The light-responsive diode can comprise a p-doped semiconductor material and an n-doped semiconductor material, with the p-doped semiconductor material and the n-doped semiconductor material forming a p-i-n diode or a p-n diode configured to generate an electric current in response to the optical signal. Forming the light-responsive diode can comprise depositing the p-doped semiconductor material, depositing the n-doped semiconductor material, and depositing an active material. The active material can be sandwiched between the p-doped semiconductor material and the n-doped semiconductor material.

The substrate can comprise a semiconductor material at the first side or between the at least one hole and the first side, and forming the light-responsive diode can comprise implanting p-type impurities into the semiconductor material and implanting n-type impurities into the semiconductor material. The implanted p-type impurities can extend a first depth into the semiconductor material and the implanted n-type impurities can extend a second depth into the semiconductor material, with the first depth greater than the second depth. The implanted p-type impurities can extend a first depth into the semiconductor material and the implanted n-type impurities can extend a second depth into the semiconductor material, with the first depth less than the second depth.

The method can further comprise forming a plurality of metal traces on the first side and configured to be flip-chip-bonded to at least one optical component and to provide electrical communication to the at least one optical component. The method can further comprise forming a plurality of metal traces on the first side and in electrical communication with the at least one photodetector. The method can further comprise forming at least one concave reflective element on the first side and configured to reflect at least a portion of the optical signal emitted from the at least one optical fiber back to the at least one photodetector.

A method of fabricating an optical system is provided. The method comprises providing a substrate comprising a first side and a second side facing generally opposite to the first side, at least one hole extending from the second side towards the first side, and at least one photodetector at the first side or between the at least one hole and the first side. The method further comprises inserting at least one optical fiber into the at least one hole, wherein the at least one optical fiber is in optical communication with the at least one photodetector. The method can further comprise flip-chip-mounting at least one optical component on the first side such that the at least one optical component is in optical communication with the at least one optical fiber and the at least one photodetector is between the at least one optical component and the at least one optical fiber. The method can further comprise inserting at least one ball lens within the at least one hole, wherein the at least one ball lens is between the at least one optical fiber and the at least one photodetector.

### BRIEF DESCRIPTION OF THE DRAWINGS

FIG. 1A schematically illustrates a cross-sectional view of an example optical system comprising a photodetector configured to be in an optical path of an optical signal transmitted through the first side of the substrate to the at least one optical fiber, in accordance with the systems and methods disclosed herein.

FIG. 1B schematically illustrates a closer cross-sectional view of the example optical system of FIG. 1A in the region of the optical aperture of the optical component, the photodetector, and the optical fiber, in accordance with the systems and methods disclosed herein.

FIG. 2A schematically illustrates a cross-sectional view of another example optical system comprising a photodetector configured to be in an optical path of an optical signal emitted from the at least one optical fiber, in accordance with the systems and methods disclosed herein.

FIG. 2B schematically illustrates a closer cross-sectional view of the example optical system of FIG. 2A in the region of the photodetector and the optical fiber, in accordance with the systems and methods disclosed herein.

FIG. 2C schematically illustrates a cross-sectional view of another example optical system comprising a photodetector and at least one concave reflective element, in accordance with the systems and methods disclosed herein.

FIG. 2D schematically illustrates a cross-sectional view of another example optical system comprising a photodetector and at least one ball lens within the at least one hole and between the optical fiber and the photodetector, in accordance with the systems and methods disclosed herein.

FIG. 3A schematically illustrates an example optical system comprising an array of holes, an array of optical fibers, and an array of photodetectors, at least some of which are configured to monitor the optical signals emitted by the optical components, and at least some of which are configured to monitor the optical signals emitted by the optical fibers, in accordance with the systems and methods disclosed herein.

FIG. 3B schematically illustrates an example optical system comprising an array of holes, an array of optical fibers, and an array of photodetectors configured to monitor the optical signals emitted by the optical components, in accordance with the systems and methods disclosed herein.

FIG. 3C schematically illustrates a closer cross-sectional view of the structure on the right side of FIG. 3A in the region between the substrate and the photodetector array chip.

FIGS. 4A and 4B schematically illustrate example isometric views of the first side of the substrate and the second side of the substrate, respectively, in accordance with the systems and methods disclosed herein.

FIGS. 5A-5C schematically illustrate isometric views of an example optical system including the optical fibers, the optical component, and the chip, in accordance with the systems and methods disclosed herein.

FIG. 6 schematically illustrates an isometric view of an example optical system an array of monolithically integrated monitor photodetectors, in accordance with the systems and methods disclosed herein.

FIG. 7 is a flowchart of an example method of fabricating an optical system in accordance with the systems and methods described herein.

FIG. 8A illustrates an example process flow of providing or fabricating an example substrate as schematically illustrated by FIG. 4A.

FIG. 8B illustrates an example process flow of assembling the example optical system of FIG. 5A.

FIG. 9A illustrates an example process flow of providing or fabricating an example substrate as schematically illustrated by FIG. 6.

FIG. 9B illustrates an example process flow of assembling the example optical system of FIG. 6.

### DETAILED DESCRIPTION

Previous passive alignment processes and structures either utilized an additional structure designed for deflecting or splitting a portion of laser light to a monitor photodetector for each laser or did not include a convenient way to include the monitor photodetector in the optical system. Certain configurations, systems, and methods described herein can utilize the dimensional control of high-precision photolithography and semiconductor processing technology to allow passive alignment of the various components without electrical probing or real-time monitoring in aligning the components during the assembly process. The assembled optical system can comprise dense integration of high speed lasers and high speed photodetectors with optical alignment to optical fibers which are perpendicularly arranged with the optical bench chip, and can be used as a core optical engine in many optical transceiver modules having many densely packaged emitting and receiving channels.

Certain configurations described herein include etching a deep hole on the backside of a substrate having an embedded etch stop layer which prevents the etched hole from extending completely through the substrate. The deep hole can be used to hold a fiber such that the fiber is vertically aligned to a flip-chip-bonded laser or photodetector chip in a manner similar to that used in the through-substrate-hole assemblies. In certain configurations described herein, the layer or layers of material that are not etched through on the front side of the substrate and remain at the end of the hole can then advantageously be processed for multiple functions. For example, the remaining layer between the optical fiber and a laser source can be designed to absorb a portion of the laser light propagating through the layer as part of a monolithically integrated monitor photodetector. For another example, active materials can be grown on the remaining layer to form a monolithically integrated signal photodetector that advantageously eliminates the need for an external photodetector chip. The monolithic integration of monitor photodetectors and signal photodetectors in certain configurations can significantly reduce chip cost and can simplify assembling processes. The existence of the etch stop layer (and the layers above it) can also enable inserting a micro-ball lens between the etch stop layer and the facet of the fiber for focusing the light to achieve higher light receiving efficiency of photodetectors with small optical apertures.

The details of the following description, made with reference to the accompanying drawings, may be found individually or combined with one another various permutations and subsets in accordance with the systems and methods disclosed herein. The example systems and methods may, however, be embodied in many different forms and should not be construed as being limited to any one particular example set forth herein. As used herein, “forming” a structure shall be given its broadest ordinary meaning, including but not limited to performing steps to make the structure or providing the structure already premade. As used herein, the term “layer” shall be given its broadest ordinary meaning including but not limited to a layer comprising a single material and having a generally uniform thickness or a varying thickness, or multiple sublayers each comprising a different material and each having either a uniform thickness or a varying thickness. In the drawings, the thicknesses of the layers and the widths of certain parts are exaggerated for clarity.

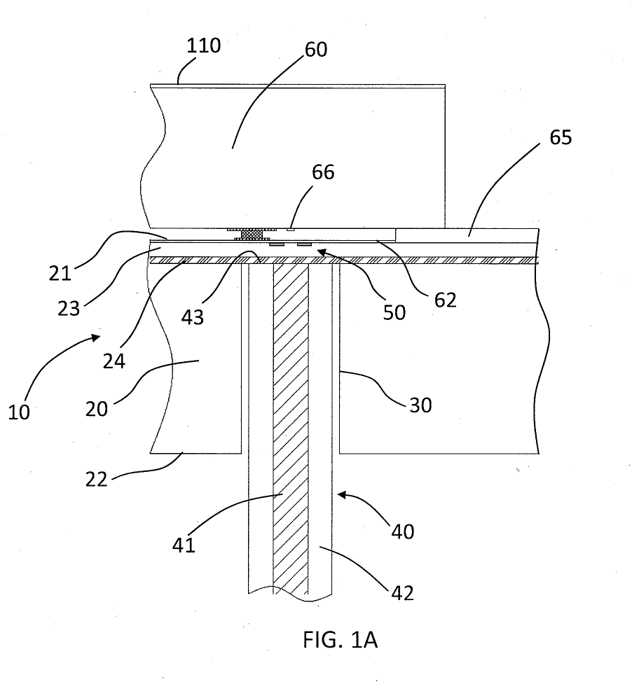

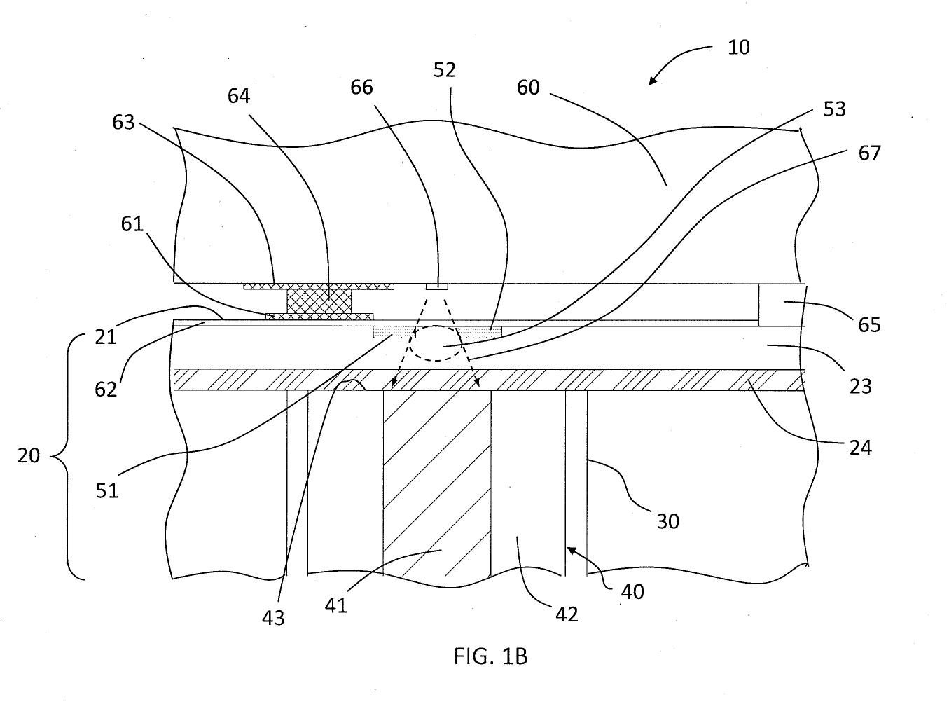

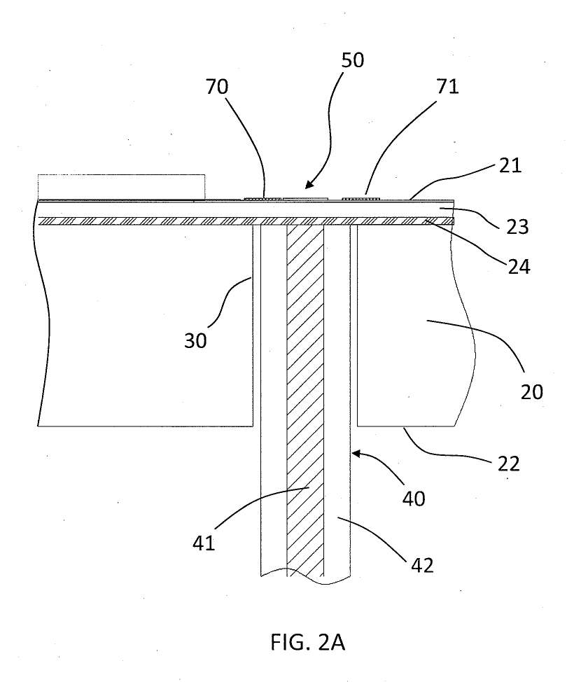

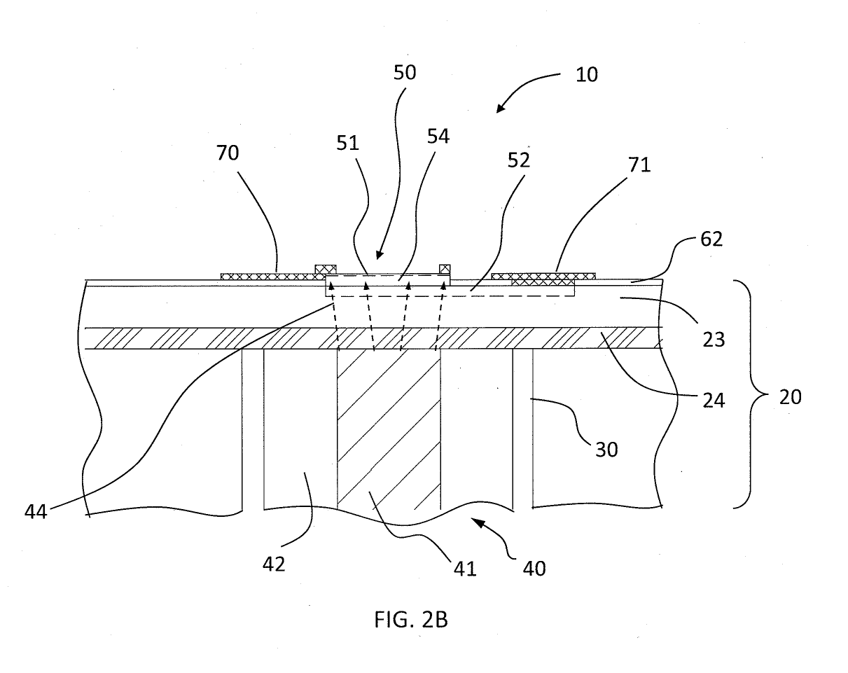

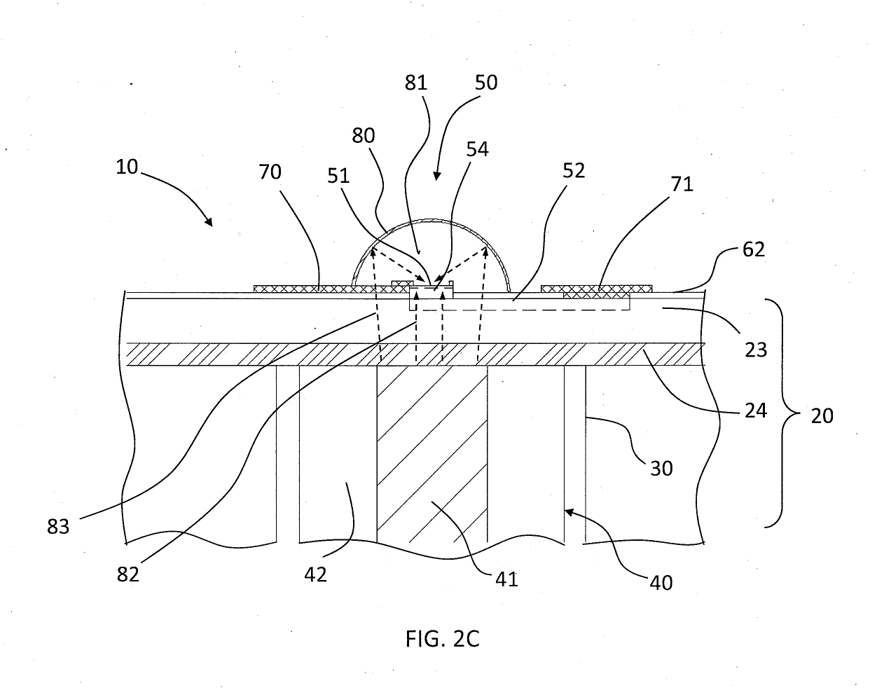

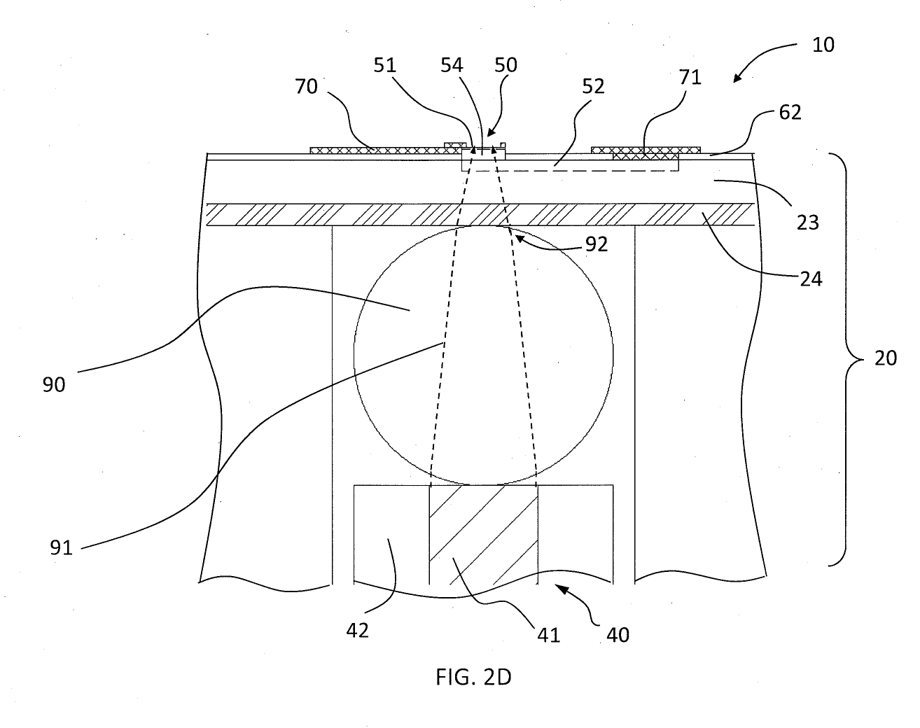

FIGS. 1A-1B and FIGS. 2A-2D schematically illustrate cross-sectional views of examples of an optical system 10 (e.g., a semiconductor optical bench device or a photonic micro assembly) in accordance with the systems and methods disclosed herein. The optical system 10 comprises a substrate 20 comprising a first side 21 and a second side 22 facing generally opposite to the first side 21. The optical system 10 further comprises at least one hole 30 extending from the second side 22 towards the first side 21. The at least one hole 30 is configured to receive at least one optical fiber 40. The substrate 20 further comprises at least one photodetector 50 at the first side 21 or between the at least one hole 30 and the first side 21. The at least one photodetector 50 is configured to be in an optical path of an optical signal emitted from the at least one optical fiber 40 or transmitted through the first side 21 to the at least one optical fiber 40. The at least one photodetector 50 is responsive to the optical signal by generating an electrical signal indicative of an intensity of the optical signal. The optical system 10 can further comprise at least one optical component 60 mounted on the first side 21 and in optical communication with the at least one optical fiber 40. The optical component 60 can have an optical aperture 66 from which the optical component 60 emits an optical signal or through which the optical component 60 receives an optical signal.

The substrate 20 can comprise a semiconductor chip comprising one or more semiconductor materials (e.g., silicon, silicon-germanium alloy, gallium arsenide, indium phosphide, indium gallium arsenide, or aluminum indium gallium arsenide). The substrate 20 can also comprise one or more layers of different materials such that the first side 21 (e.g., the front side) of the substrate 20 and the second side 22 (e.g., the back side) of the substrate 20 can comprise the same material as one another but that is different than a material within the substrate 20 between the first side 21 and the second side 22, or the first side 21 can comprise a different material than the second side 22 of the substrate 20. The thickness of the substrate 20 between the first side 21 and the second side 22 can be in a range between about 200 microns and about 2000 microns, and is typically smaller than either the width or the length of the substrate 20. One or both of the first side 21 and the second side 22 can have a smooth surface (e.g., by being polished) prior to any subsequent process steps are implemented.

As described more fully below, at least one of the semiconductor materials of the substrate 20 can be used in the at least one photodetector 50. For example, the substrate 20 can comprise gallium arsenide and lattice-matched gallium indium phosphide on the gallium arsenide, and the at least one photodetector 50 can comprise a semiconductor material 23 (e.g., a portion of the lattice-matched gallium indium phosphide) in the optical path. For another example, the substrate 20 can comprise silicon and a silicon oxide layer, and the semiconductor material 23 can comprise silicon between the silicon oxide layer and the first side 21. The semiconductor material 23 can be selected to absorb at least a portion of the light propagating to or from the at least one optical fiber 40.

As schematically illustrated by FIGS. 1A-1B and 2A-2D, the substrate 20 can comprise an etch stop layer 24 (e.g., comprising the silicon oxide layer) between the at least one hole 30 and the semiconductor material 23 (e.g., silicon between the silicon oxide layer and the first side 21). The etch stop layer 24 can serve to terminate the etching of the substrate 20 during the formation of the at least one hole 30. The etch stop layer 24 can comprise a different material than the rest of the substrate 20 and can be highly resistant to the selected etching process used to etch the substrate 20 to form the at least one hole 30. In addition, the etch stop layer 24 can comprise a material that does not absorb, or only weakly absorbs, the light propagating to or from the at least one optical fiber 40, thereby allowing most of the light to be transmitted through the etch stop layer 24.

For example, the etch stop layer 24 can comprise silicon oxide (e.g., silicon dioxide) deposited on top of the substrate 20 and the semiconductor material 23 can comprise polycrystalline silicon subsequently deposited on the etch stop layer 24. Example deposition methods compatible with the systems and methods described herein include, but are not limited to, plasma-enhanced chemical vapor deposition, thermal oxidation, and low pressure vapor deposition. The silicon oxide of the etch stop layer 24 exhibits a very low etch rate for certain plasma etching recipes which can be used to etch the underlying silicon of the substrate 20, so it can be used to terminate the etching of the substrate 20 during formation of the at least one hole 30. The semiconductor material 23 (e.g., polycrystalline silicon) can absorb light with wavelengths below 1100 nanometers, so it can be used to monitor some commonly used communication wavelengths including but not limited to 850 nanometers and 980 nanometers.

For another example, the substrate 20 can comprise a silicon-on-insulator (SOI) structure having silicon (e.g., crystalline silicon or polysilicon) and an oxide layer (e.g., silicon oxide layer) at a depth below the first side 21 and separating a silicon layer above the oxide layer and the silicon of the substrate 20 below the oxide layer. The silicon above the oxide layer can serve as the semiconductor material 23 of the at least one photodetector 50.

The SOI substrate can made by sandwiching an insulator layer (e.g., silicon oxide) between two single crystalline silicon layers using various methods including but not limited to separation by implantation of oxygen and wafer bonding. SOI substrates can advantageously save the effort of depositing the semiconductor material 23 and the etch stop layer 24 and can advantageously offer a better quality of silicon material of the semiconductor material 23 for monitoring optical power. Similarly, if the substrate 20 comprises gallium arsenide, lattice-matched gallium-indium phosphide can be used as the etch stop layer 24 and gallium arsenide can be used as the semiconductor material 23 by using single crystalline epitaxy methods including but not limited to metal-organic chemical vapor deposition.

The thicknesses of the semiconductor material 23 and the etch stop layer 24 can be selected in view of a few factors. The etch stop layer 24 can be selected to be thick enough to withstand the over etch of the etching of the formation of the at least one hole 30 if the material of the etch stop layer 24 does not ideally resist the etching. The thickness of the semiconductor material 23 can be selected to absorb a predetermined portion of the laser light (e.g., in a range between 1% and 10%). For example: if the semiconductor material 23 comprises silicon and the wavelength of the laser light is 850 nanometers, a thickness of 1.5 microns corresponds to 10% absorption as the optical absorption coefficient of silicon at 850 nanometers is 0.07/micron. In addition, as described herein, the thicknesses of the semiconductor material 23 and the etch stop layer 24 are factors in the geometrical aspects of the propagation of light to and from the at least one optical fiber 40. Example thicknesses of the silicon oxide etch stop layer 24 can be between 0.375 micron and 5 microns, and example thicknesses of the silicon semiconductor material 23 on the etch stop layer 24 can be between 0.25 micron and 13 microns.

The at least one hole 30 can comprise an array of holes 30 each extending from the second side 22 of the substrate 20 towards the first side 21 of the substrate 20 and that are spaced from one another at predetermined intervals. The at least one hole 30 can extend into the substrate 20 towards the first side 21 by 200 to 700 microns, depending on the thickness of the substrate 20 being used. The distribution of the holes 30 can be selected to facilitate convenience of making connections to other components, such as transimpedance amplifiers, limiting amplifiers, and laser drivers of the optical communication system. For example, a chess-board-type of arrangement can be used with a hole center to adjacent hole center distance of 250 microns or 127 microns along two perpendicular directions.

The at least one hole 30 (e.g., an array of holes 30) can be formed using photolithography techniques, including but not limited to plasma etching and wet chemical etching, and can be aligned with patterns and structures of the front side 21. The at least one hole 30 does not extend through the entire substrate 20. For example, as described herein, the etching of the substrate 20 to form the hole 30 is terminated at the etch stop layer 24 which is close to, but below, the front surface 21 of the substrate 20. Such holes 30 can advantageously prevent direct contact of the optical fiber 40 within the hole 30 with an optical aperture surface of an optical component (e.g., laser or a photodetector) in optical communication with the optical fiber 40, thus preventing damaging either or both of them. For example, as schematically illustrated by FIGS. 1A and 1B, at least a portion of the semiconductor material 23 and at least a portion of the etch stop layer 24 are between the optical fiber 40 and an optical component 60 (e.g., a laser source) that is mounted on the first side 21 of the substrate 20. Such holes 30 can also advantageously prevent the contamination of the optical fiber 40 by adhesives, which may be applied in the gap between the substrate 20 and the optical component 60 (e.g., a laser array chip or a photodetector array chip) that is flip-chip bonded to the substrate 20.

The holes 30 can be sized or otherwise configured to receive optical fibers 40 inserted into the holes 30 from the second side 22 of the substrate 20, as schematically illustrated by FIGS. 1A-1B and 2A-2D, and to confine movement of the fiber 40 once the fiber 40 is affixed in the hole 30. For example, the at least one hole 30 can have a substantially circular cross-section in a plane generally perpendicular to the hole 30 or generally parallel to the first side 21 and the second side 22 (e.g., the hole 30 can extend perpendicularly through at least a portion of the substrate 20). The substantially circular cross-section of the hole 30 can have a diameter (e.g., between 125 microns and 150 microns) or perimeter that is substantially the same or larger than the corresponding diameter (e.g., 125 microns) or perimeter of the optical fiber 40 that is to be inserted into the hole 30 to facilitate the insertion of the optical fibers 40 by compensating for imperfections of the holes 30 and errors of the fiber diameter. For a silica optical fiber including the core, cladding, and buffer regions having a diameter of around 250 microns (after stripping off the protective polymer coating), the diameter the corresponding hole 30 can be 5-30 microns larger (e.g., 255 microns to 280 microns).

Other sizes and shapes of the cross-section of the hole 30 (e.g., square, hexagon, octagon) which can tightly confine a cylinder-shaped optical fiber 40 are also compatible with the systems and methods disclosed herein. For example, the hole 30 can comprises a center portion and a plurality of portions extending outwardly from the center portion. The extended portions can be used as channels for receiving adhesives (e.g., glue or epoxy) for fixing the optical fiber 40 to the substrate 20 upon installation. U.S. patent application Ser. No. 13/476,668, filed on May 21, 2012 and incorporated in its entirety by reference herein, discloses various configurations of the at least one hole 30 that are compatible with the systems and methods disclosed herein.

The at least one hole 30 is configured to receive at least one optical fiber 40 (e.g., an array of optical fibers 40). For example, the at least one optical fiber 40 can be mounted to the substrate 20 with a portion of the at least one optical fiber 40 (e.g., a portion of the core 41 and the cladding 42) within the at least one hole 30 such that the end facet 43 of the optical fiber 40 is within the hole 30. The at least one optical fiber 40 can be in optical communication with the at least one photodetector 50, as described more fully below.

The optical fibers 40 can comprise silica or plastic materials and can include a transparent core surrounded by a transparent cladding material with a lower index of refraction than that of the core. Light can be substantially confined in the core by total internal reflection such that the fiber functions as a waveguide to transmit light between two ends of the fiber 40. Examples of optical fibers 40 compatible with the systems and method disclosed herein include, but are not limited to, single-mode fibers (e.g., supporting a single transverse mode), multimode fibers (e.g., supporting multiple transverse modes), lens fibers, and polarization-maintaining fibers. The width or diameter of the core 41 for a single mode fiber 40 can be about 10 microns, while the width or diameter of the core 41 for a multi-mode fiber 40 can be between 50 microns and 62.5 microns. The diameter of the core of a multi-mode fiber can be larger than that of a single mode fiber, which can make multimode fibers easier to align within the tolerances of the resultant micro assembly device and process.

The at least one photodetector 50 (e.g., an array of photodetectors 50) can be at the first side 21 (e.g., at least a portion of the photodetector 50 can be part of the surface of the first side 21) or can be between the at least one hole 30 and the first side 21 (e.g., at least a portion of the photodetector 50 is below the surface of the first side 21 and is above the hole 30). The at least one photodetector 50 can comprise a light-responsive diode in the optical path of an optical signal emitted from the at least one optical fiber 40 or transmitted through the first side 21 to the at least one optical fiber 40. The at least one photodetector 50 is responsive to the optical signal by generating an electrical signal indicative of an intensity of the optical signal. For example, the light-responsive diode can comprise a p-doped region 51 (e.g., a region of the semiconductor material 23 doped with p-type impurities) and an n-doped region 52 (e.g., a region of the semiconductor material 23 doped with n-type impurities) that form a p-i-n diode or a p-n diode that is configured to generate an electric current in response to the optical signal.

FIGS. 1A-1B schematically illustrate an example optical system 10 comprising a photodetector 50 configured to be in an optical path of an optical signal transmitted through the first side 21 to the at least one optical fiber 40. The optical signal is emitted from an optical component 60 (e.g., a surface emitting light source) mounted on the first side 21 such that the optical component 60 is in optical communication with the at least one optical fiber 40 with the optical path extending through the first side 21 and between the at least one optical component 60 and the at least one optical fiber 40. The photodetector 50 is positioned to receive the optical signal from an optical component 60 (e.g., the photodetector 50 comprises a light-responsive p-i-n diode in the optical path of the optical signal transmitted through the first side 21 to the at least one optical fiber 40). The p-i-n diode of the photodetector 50 comprises a p-doped region 51 of the semiconductor material 23, an n-doped region 52 of the semiconductor material 23, and a near-intrinsic region 53 of the semiconductor material 23 between the p-doped region 51 and the n-doped region 52. The example photodetector 50 of FIGS. 1A-1B has the p-i-n diode oriented generally parallel to the first side 21 of the substrate 20 (e.g., a line extending from the p-doped region 51 to the n-doped region 52 is generally parallel to the first side 21).

The p-doped region 51 and the n-doped region 52 can be electrically connected to a cathode metal line and an anode metal line (not shown in FIGS. 1A-1B), respectively, such that the p-i-n diode is reversely biased by an applied voltage. A portion of the near-intrinsic region 53 (roughly circled by the dashed line) can absorb a small portion of the laser light propagating through the semiconductor material 23, as explained above. The reversely biased p-i-n diode can collect the photocarriers generated by the absorption of the optical signal by the semiconductor material 23 to provide the electric current (e.g., photocurrent) indicative of the intensity of the optical signal to external circuitry to calculate the optical power of the optical signal. This example monolithically integrated monitor photodetector 50 can advantageously eliminate the need for a separate external monitor photodetector and for micro-optical structures for deflecting or splitting a portion of the optical signal to the external monitor photodetector.

The optical system 10, as schematically illustrated by FIGS. 1A-1B, can comprise at least one metal layer 61 at the first side 21 and configured to be in electrical communication with at least one optical component 60 mounted on the first side 21. For example, the substrate 20 can comprise a plurality of metal traces (e.g., an array of metal traces) at the first side 21 that are configured to be connected to the at least one optical component 60 (e.g., by flip-chip bonding) and to provide electrical communication to the at least one optical component 60. The optical system 10 can further comprise at least one electrically insulative layer 62 (e.g., silicon oxide or silicon dioxide) between the at least one metal layer 61 and the at least one hole 30 (e.g., between the metal layer 61 and the semiconductor material 23). The electrically insulative layer 62 can be configured to electrically isolate the metal layers 61 from other portions of the optical system 10. At least a portion of the electrically insulative layer 62 can be in the optical path of the optical signal propagating between the optical component 60 and the optical fiber 40, or a portion of the electrically insulative layer 62 can be removed (e.g., etched away during fabrication) to eliminate or reduce the optical absorption of the optical signal by the electrically insulative layer 62.

As schematically illustrated by FIGS. 1A-1B, the optical system 10 can comprise at least one optical component 60 mounted on the first side 21 of the substrate 20. For example, the optical component 60 can comprise a laser array chip installed upside down on top of the substrate 20 using flip-chip bonding techniques. For example, a metal pad 63 of the optical component 60 can be aligned with a metal layer 61 of the substrate 20, and the optical component 60 can be compressed onto the substrate 20 while heating up the assembly to melt a metal solder bump 64 to connect the metal pad 63 and the metal layer 61. Ultrasonic pulse can be used during the compression process to facilitate the metal-to-metal bonding. The solder bump 64 can comprise one or more materials with good electrical conductivity and low melting temperature, including but not limited to gold, gold-tin alloy, and lead-tin alloy. The metal layer 61 and the metal pad 63 can comprise aluminum, gold, or other metal. If aluminum is used, a thin multi-layer structure called “under bump metallurgy” (UBM) can be used, which can form an adhesion and diffusion barrier between the aluminum metal pad 63 and the solder bump 64.

As schematically illustrated by FIGS. 1A and 1B, the substrate 20 can comprise at least one spacer 65 at the first side 21 configured to stop or hold the optical component 60 from further advancing towards the underlying layers of the substrate 20 during the compression of the flip-chip bonding process. The spacer 65 can determine or control the final height of the optical component 60 over the first side 21, as well as the distance between the optical aperture 66 of the optical component 60 (e.g., laser) and the surface of the first side 21 of the substrate 20. For example, this distance can be in, but is not limited to, a range between 5 microns to 50 microns. The gap between the optical component 60 and the first side 21 of the substrate 20 also enables the insertion of adhesives which can be used to glue the optical component 60 and the substrate 20 together after flip-chip bonding for better mechanical reliability.

The thickness of the spacer 65, along with the thicknesses of the semiconductor material 23, the etch stop layer 24, and the electrically insulative layer 62, can contribute to the distance between the optical aperture 66 of the optical component 60 and the end facet 43 of the optical fiber 40. For example, in configurations in which the optical component 60 emits an optical signal to be received by the optical fiber 40, the thickness of the spacer 65 can be selected such that the core 41 of the optical fiber receives most of the divergent light (denoted by dashed lines 67) emitted from the optical aperture 66 of the optical component 60.

FIGS. 2A-2B schematically illustrate another example photodetector 50 comprising a light-responsive p-i-n diode in the optical path of an optical signal emitted from the at least one optical fiber 40. The p-i-n diode of the photodetector 50 comprises a p-doped region 51, an n-doped region 52, and a region 54 (e.g., an active semiconductor region) sandwiched between the p-doped region 51 and the n-doped region 52. The example photodetector 50 of FIGS. 2A-2B has the p-i-n diode oriented generally perpendicular to the first side 21 of the substrate 20 (e.g., a line extending from the p-doped region 51 to the n-doped region 52 is generally perpendicular to the first side 21) and can be designed for operations of high-speed communications since this configuration can enable high-speed operation by reducing the distance that photo-generated electrons and holes travel. While the example photodetector 50 of FIGS. 2A-2B has the n-doped region 52 comprising an n-doped portion of the semiconductor material 23, the region 54 over the n-doped region 52, and the p-doped region 51 over the region 54, other example configurations of the photodetector 50 can have the p-doped region 51 comprising a p-doped portion of semiconductor material 23, the region 54 over the p-doped region 51, and the n-doped region 52 over the region 54. The region 54 can be strongly absorbing of the light carried by the optical fiber 40 (e.g., in configurations in which the optical signal does not need to propagate past the photodetector 50).

The p-doped region 51 and the n-doped region 52 can be electrically connected to metal lines 70, 71, respectively, (e.g., a signal metal line and a ground metal line) such that the p-i-n diode is reversely biased by an applied voltage. The region 54 can absorb a portion of the optical signal propagating from the optical fiber 40, as explained above. The reversely biased p-i-n diode can collect the photocarriers generated by the absorption of the optical signal by the region 54 to provide the electric current (e.g., photocurrent) indicative of the intensity of the optical signal to external circuitry to calculate the optical power of the optical signal.

The region 54 can be formed in a mesa structure or layer to facilitate confinement of the photocarriers (e.g., the photo-generated electrons and holes). The thickness of the region 54 can be configured to enable high speed operation by reducing the distance that the photo-generated electrons and holes travel. For example, the thickness of the region 54 can be about 2 microns to 3 microns for operation at 10 GHz or 10 Gb/s, and can be less than 1 micron for operation at 25 GHz or 25 Gb/s. The region 54 can comprise a material with a strong optical absorption at the operating wavelength such that the region 54 is able to absorb most of the light coming out of the optical fiber 40. The material of the region 54 can be selected to be epitaxially grown on top of the semiconductor material 23 (e.g., resulting in a crystalline active layer material for good high speed performance). For example, for a semiconductor material 23 comprising silicon (e.g., a layer of a silicon-on-insulator substrate) and an operating wavelength of 850 nanometers, germanium may be selected for the region 54. The optical absorption of germanium at 850 nanometers is about 4/micron, therefore 1 micron of germanium absorbs more than 98% of the light at this wavelength. Similarly, if the semiconductor material 23 comprises indium phosphide, lattice-matched indium gallium arsenide may be used for the region 54.

The optical signal emitted from the optical fiber 40 can propagate to the bottom of the region 54 and can be absorbed by the region 54. As schematically illustrated by FIG. 2B, the optical signal may diverge (denoted by the dashed arrows 44) upon being emitted from the fiber core 41. The divergence angle is usually small for many optical fibers 40, and the width or diameter of the photodetector mesa comprising the region 54 (e.g., the optical aperture of the photodetector 50) can be slightly larger than the width or diameter of the fiber core 41. For example, the core of an OM3 multi-mode fiber is 50 microns, and the diameter of the photodetector mesa comprising the region 54 can be about 60 microns. Such a configuration can be compatible with operations at 10 GHz or 10 Gb/s. If a smaller mesa is desired, other configurations can be used as described below.

FIG. 2C schematically illustrates a cross-sectional view of another example optical system 10 comprising a monolithically integrated photodetector 50. The optical system 10 of FIG. 2C comprises at least one concave reflective element 80 on the first side 21 (e.g., a semi-spherical concave mirror structure formed over or on top of the photodetector 50). The photodetector 50 of FIG. 2C is similar to that schematically shown in FIG. 2B, except for a smaller mesa of the region 54 and the region 81 between the concave reflective element 80 and the photodetector 50. The reflective element 80 can comprise a transparent material with its surface coated with a reflective material, such as one or metal layers. The reflective element 80 can be configured to reflect at least a portion of the optical signal emitted from the at least one optical fiber 40 back to the at least one photodetector 50.

The optical system 10 schematically shown in FIG. 2C is compatible with operation at very high speed (e.g., 25 Gb/s, 40 Gb/s, or higher) and uses a small mesa (e.g., less than 30 microns in width or diameter) which can advantageously reduce the junction capacitance which causes resistance-capacitance (RC) delay. The small mesa has a correspondingly small optical aperture, which may not capture all of the light emitted from the at least one optical fiber 40, especially when the fiber core 41 is large (e.g., having a diameter of 50 microns, such as for an OM3 multi-mode optical fiber). A portion of the optical signal (e.g., shown by dashed lines 82) can be within the optical aperture of the photodetector 50 and can be directly absorbed by the region 54. Another portion of the optical signal (e.g., shown by dashed lines 83) can pass through or around the region 54 mesa of the photodetector 50, and can be reflected by the concave reflective element 80 back to the mesa of the region 54 of the photodetector 50 to be absorbed by the region 54 through top incidence. Therefore, the reflective element 80 advantageously increases the optical absorption efficiency for a small diameter photodetector 50.

The reflective element 80 can be fabricated by reflowing or molding of soft and transparent materials, including but not limited to photoresist, bisbenzocyclobutene (BCB), polyimide or other polymers. For example, the reflective element 80 can be fabricated by depositing and defining a photosensitive polymer material followed by thermal reflow in an inert gas ambient atmosphere to shape the reflective element 80. Such fabrication techniques are widely used in imaging charge-coupled device (CCD) fabrication and in a variety of other sensors industries. The shape of the reflective element can be a semi-sphere, an imperfect semi-sphere, or other shape (e.g., concave) that reflects light back towards the photodetector 50 with various efficiencies. The height of the reflective element 80 above the first side 21 can be in, but is not limited to, a range between 20 microns and 50 microns, and the width or diameter of the reflective element 80 in a plane generally parallel to the first side 21 can be slightly larger than the width or diameter of the optical fiber core 41 (e.g., to reflect a substantial fraction of the divergent light or all of the divergent light).

FIG. 2D schematically illustrates a cross-sectional view of another example optical system 10 comprising a monolithically integrated photodetector 50. The optical system 10 comprises at least one ball lens 90 within the at least one hole 30 and between the at least one optical fiber 40 and the at least one photodetector 50 (e.g., within the at least one hole 30 of FIG. 2A). For example, a substantially transparent ball lens 90 can be inserted inside the hole 30 between the optical fiber 40 and the etch stop layer 23. The ball lens 90 can advantageously couple light efficiently from the optical fiber 40 to the monolithically integrated photodetector 50 (e.g., where the width or diameter of the fiber core 41 is larger than the width or diameter of the optical aperture of the photodetector 50).

The width or diameter of the ball lens 90 can be similar to the width or diameter of the optical fiber 40 such that the ball lens 90 fits tightly inside the hole 30. The ball lens 90 can comprise one or more transparent materials (e.g., silica) which are easily made into a spherical shape (e.g., by molding or other methods). The ball lens 90 can advantageously deflect the light emitted from the optical fiber 40 and can effectively focus the light propagating through, into, and out of the ball boundaries (e.g., as shown by the dashed lines 91 of FIG. 2D). For example, a silica ball lens 90 can have a width or diameter of 125 microns, substantially equal to the width or diameter of an OM3 optical fiber. Such a ball lens 90 can focus a light beam having a width or diameter of 50 microns (e.g., the OM3 optical fiber core width or diameter) into a light cone having an initial width or diameter less than 20 microns at the exit facet 92 of the ball lens 90 with a focal point at a distance of approximately 16 microns from the exit facet 92 of the ball lens 90. Using such a configuration, a photodetector 50 with a 20-micron optical aperture can be placed at any distance between zero to 32 microns away from the exit facet 92 of the ball lens 90 to receive a substantial fraction of the light or all of the light. The use of the ball lens 90 can affect the selection of the thicknesses of the materials or layers between the optical fiber 40 and the photodetector 50 (e.g., the semiconductor material 23 and the etch stop layer 24) or can compensate for thicknesses of these materials or layers dictated by other (e.g., non-optical) considerations.

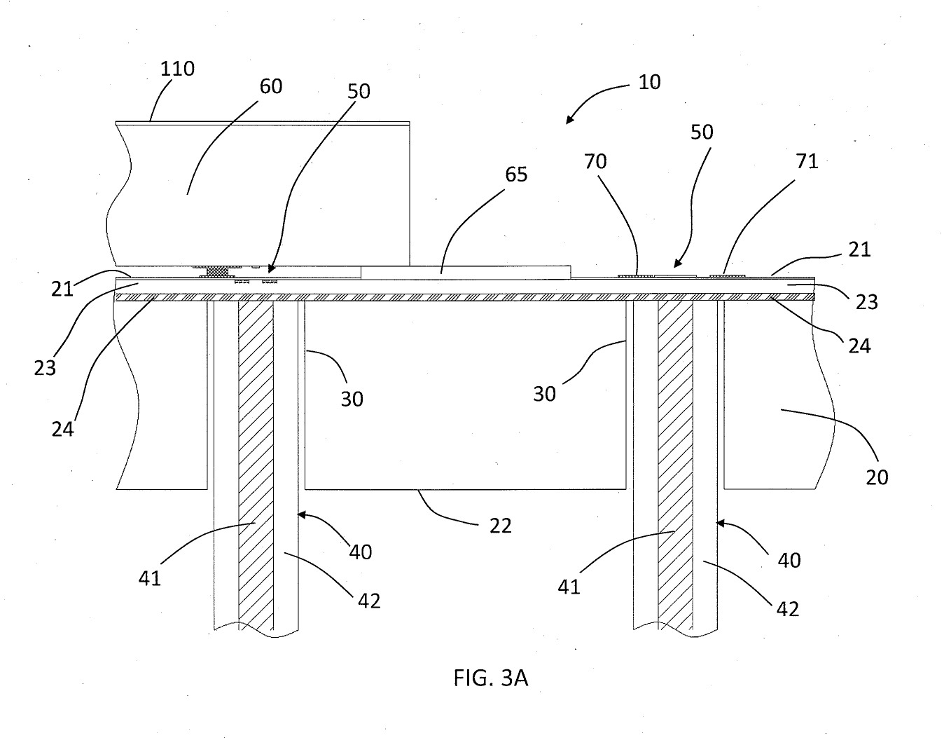

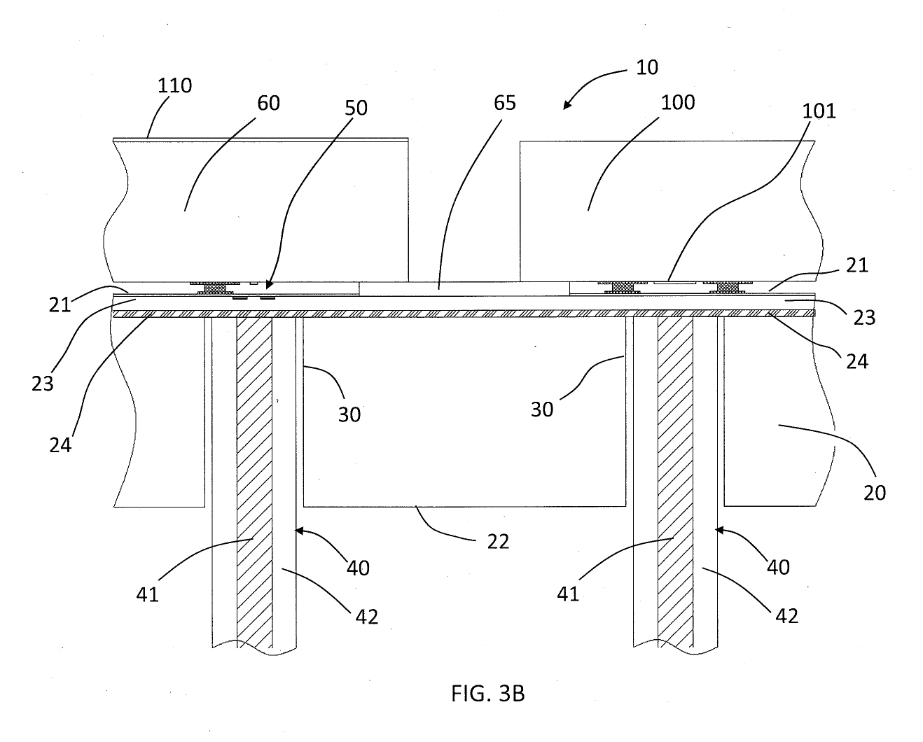

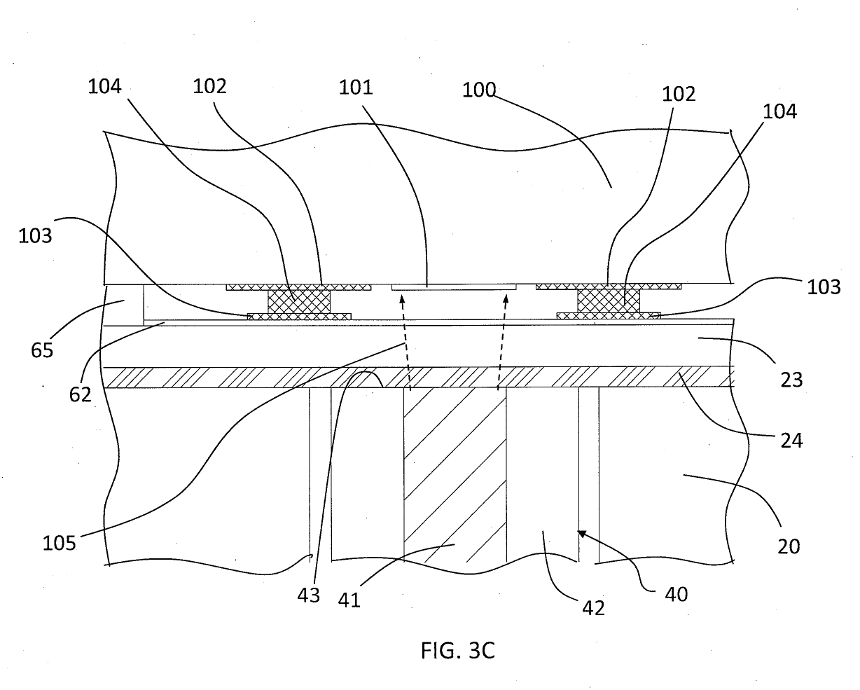

FIG. 3A schematically illustrates an example optical system 10 comprising an array of holes 30, an array of optical fibers 40, and an array of photodetectors 50. At least some of the photodetectors 50 are configured to monitor the optical signals emitted by the optical components 60 (e.g., on the left side of FIG. 3A) and at least some of the photodetectors 50 are configured to monitor the optical signals emitted by the optical fibers 40 (e.g., on the right side of FIG. 3A). While the left side of FIG. 3A shows a photodetector 50 such as the one schematically illustrated by FIG. 1B in optical communication with the optical component 60, this photodetector 50 can instead comprise a photodetector 50 such as the one schematically illustrated by FIG. 2B. In addition, while the right side of FIG. 3A shows a photodetector 50 comprising a photodetector 50 such as the one schematically illustrated by FIG. 2B in optical communication with the optical fiber 40, this photodetector 50 can instead comprise a photodetector 50 such as the one schematically illustrated by FIG. 1B.

FIG. 3B schematically illustrates an example optical system 10 comprising an array of holes 30, an array of optical fibers 40, and an array of photodetectors 50 configured to monitor the optical signals emitted by the optical components 60 (e.g., on the left side of FIG. 3B). The example optical system 10 of FIG. 3B also comprises at least one photodetector array chip 100 configured to monitor the optical signals emitted by at least one optical fiber 40 (e.g., on the right side of FIG. 3B). FIG. 3C schematically illustrates a closer cross-sectional view of the structure at the right side of FIG. 3B in the region between the substrate 20 and the photodetector array chip 100. The photodetector array chip 100 can comprise an optical aperture 101 and a plurality of metal pads 102 configured to be electrically coupled to corresponding metal layers 103 of the substrate 20 (e.g., by solder bumps 104) upon installing the photodetector array chip 100 on top of the substrate 20 using flip-chip bonding techniques.

The flip-chip bonding process can include aligning the metal pads 102 of the photodetector array chip 100 and the metal layers 103 of the substrate 20, while heating up the substrate 20 and the chip 100 to melt the solder bumps 104 to electrically connect the chip 100 to the substrate 20. Ultrasonic pulses may be used during the compression process to facilitate the metal-to-metal bonding.

The spacer 65 can be configured to stop or hold the photodetector array chip 100 from further advancing towards the underlying layers of the substrate 20 during the compression of the flip-chip bonding process. The spacer 65 can determine or control the final height of the chip 100 over the first side 21, as well as the distance between the optical aperture 101 of the chip 100 and the surface of the first side 21 of the substrate 20. For example, this distance can be in, but is not limited to, a range between 5 microns to 50 microns. The gap between the chip 100 and the first side 21 of the substrate 20 also enables the insertion of adhesives which can be used to glue the chip 100 and the substrate 20 together after flip-chip bonding for better mechanical reliability. The distance between the optical aperture 101 and the fiber end facet 43 can be selected to allow the optical aperture 101 to receive most of the divergent light coming out of the fiber core 41 (e.g., as shown by the dashed lines 105). The etch stop layer 24 can comprise a material that does not absorb, or only weakly absorbs, the light propagating to or from the at least one optical fiber 40, thereby allowing most of the light to be transmitted through the etch stop layer 24. In the region schematically shown in FIG. 3C, one or both of the semiconductor material 23, the etch stop layer 24, and the electrically insulative layer 62 can be etched away from the optical path between the chip 100 and the optical fiber 40 to eliminate the optical loss if it is not acceptable in some applications.

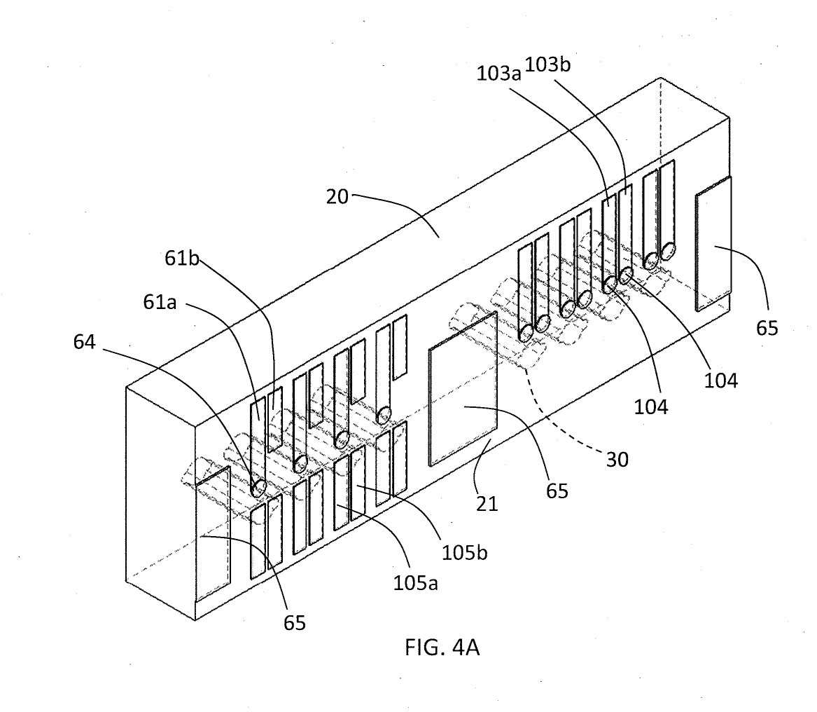

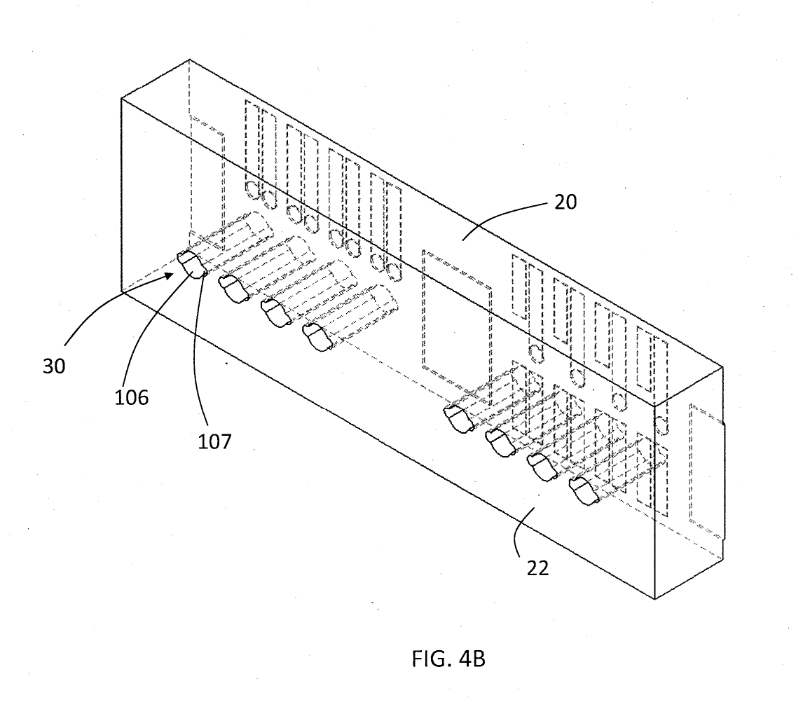

FIGS. 4A and 4B schematically illustrate example isometric views of the first side 21 of the substrate 20 and the second side 22 of the substrate 20, respectively. Although FIGS. 4A and 4B show a substrate 20 configured to be mounted to an optical component 60 comprising a single-row four-device array chip, the optical system 10, the photodetector array, the hole array, and the fiber array are not limited to arrays having a certain number of elements or a certain number of dimensions. For example, pluralities of photodetectors, holes, and fibers can be configured in two dimensional arrays (e.g., having rows and columns).

The metal layers 61 and the solder bumps 64 can be configured to be flip-chip bonded to the optical component 60. For example, for an optical component 60 comprising a laser array chip, the metal layers 61 can comprise pairs of signal metal lines 61a and ground metal lines 61b that match the number of lasers on the laser array chip. Example signal metal lines 61a can have widths in a direction parallel to the first side 21 that are in, but are not limited to, a range that is between 1 micron to 50 microns. Example ground metal lines 61b can have widths in a direction parallel to the first side 21 that are wider than the signal metal lines 61a and can be in, but not limited to, a range between 20 microns to a few hundreds of microns. The ground metal lines 61b can be connected together to form a larger ground plane in order to minimize electrical noise. The layout of the signal metal lines 61a and the ground metal lines 61b can be selected to form a transmission line system with 50-ohm characteristic impedance in order to minimize electrical reflection at high speed operations. The metal solder bump 64 can be formed on one end of a signal metal line 61a to provide electrical interconnection between the signal metal line 61a and the signal metal pad of a laser of the optical component 60.

The metal layers 103 and the solder bumps 104 can be configured to be connected to the photodetector array chip 100 (e.g., by flip-chip bonding). For example, for a chip 100 comprising a number of photodetectors, the metal layers 103 can comprise pairs of signal metal lines 103a and ground metal lines 103b that match the number of photodetectors on the chip 100. Example signal metal lines 103a can have widths in a direction parallel to the first side 21 that are in, but are not limited to, a range that is between 1 micron to 50 microns. Example ground metal lines 103b can have widths in a direction parallel to the first side 21 that are wider than the signal metal lines 103a and can be in, but not limited to, a range between 20 microns to a few hundreds of microns. The ground metal lines 103b can be connected together to form a larger ground plane in order to minimize electrical noise. The layout of the signal metal lines 103a and the ground metal lines 103b can be selected to form a transmission line system with 50-ohm characteristic impedance in order to minimize electrical reflection at high speed operations. The metal solder bump 104 can be formed on one end of a signal metal line 103a and on one end of a ground metal line 103b to provide electrical interconnection between the signal metal line 103a and the signal metal pad of the chip 100 and between the ground metal line 103b and the ground metal pad of the chip 100.

The substrate 20 can also comprise pairs of cathode metal lines 105a and anode metal lines 105b on the first side 21 of the substrate 20 and configured to provide electrical communication with the p-doped regions 51 and the n-doped regions 52 of the photodetectors 50. These metal lines 105a, 105b can be positioned in locations that are opposite to those of the signal metal line 61a and the ground metal line 61b, as schematically illustrated by FIG. 4A. The cathode metal line 105a and the anode metal line 105b can be configured to be connected to external circuits for managing the photocurrent generated by the photodetectors 50.

As schematically illustrated by FIG. 4B, the at least one hole 30 can comprise an array of holes 30 each extending from the second side 22 of the substrate 20 towards the first side 21 of the substrate 20, but not through the first side 21 of the substrate 20, and that are spaced from one another at predetermined intervals. The holes 30 can be sized or otherwise configured to receive the optical fibers 40 inserted into the holes 30 from the second side 22 of the substrate 20. For example, the hole 30 can comprises a center portion 106 and one or more portions 107 extending outwardly from the center portion 106. The extended portions 107 can be used as channels for receiving adhesives (e.g., glue or epoxy) for fixing the optical fiber 40 to the substrate 20 upon installation. U.S. patent application Ser. No. 13/476,668, filed on May 21, 2012 and incorporated in its entirety by reference herein, discloses various configurations of the holes 30 that are compatible with the systems and methods disclosed herein.

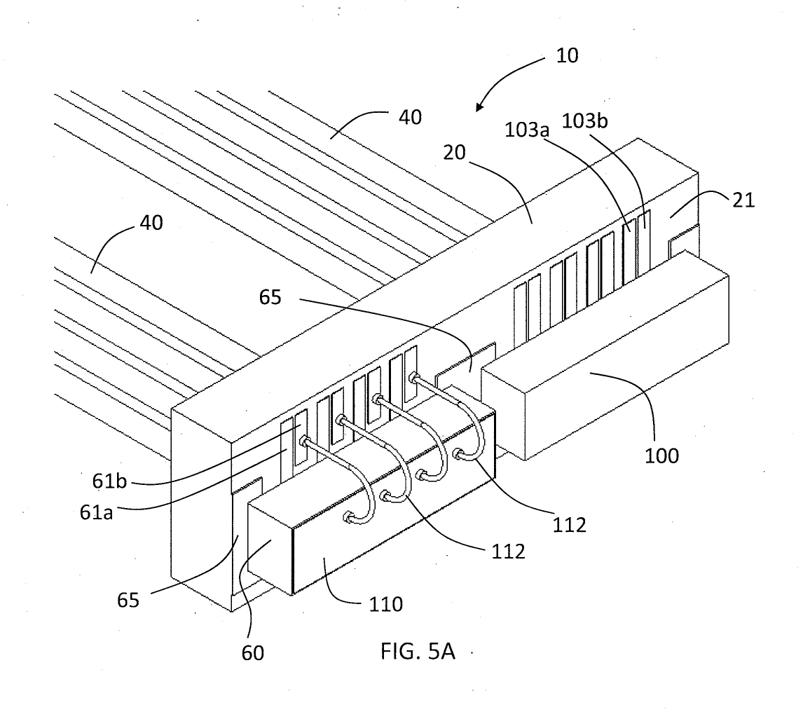

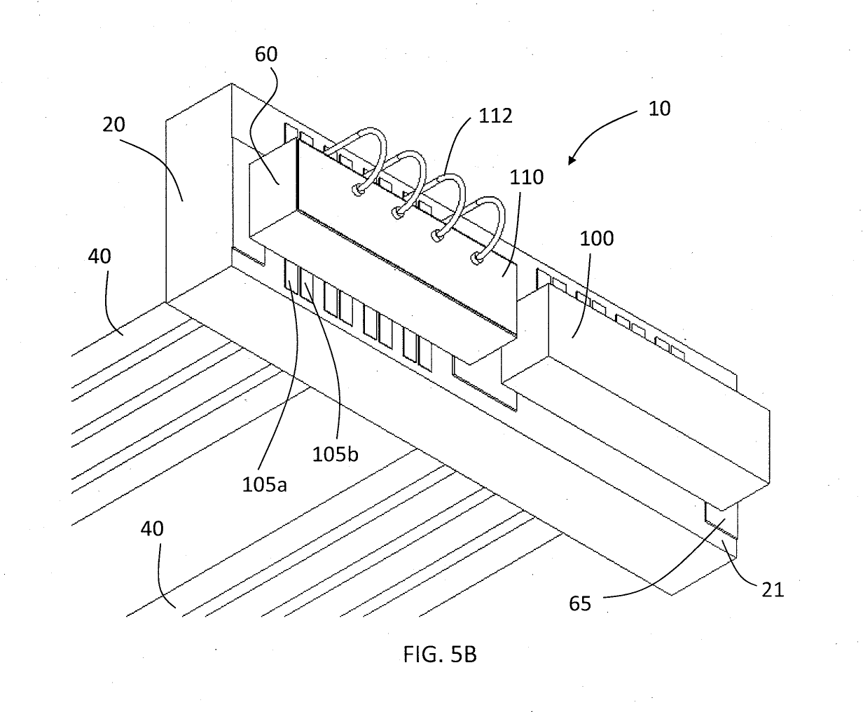

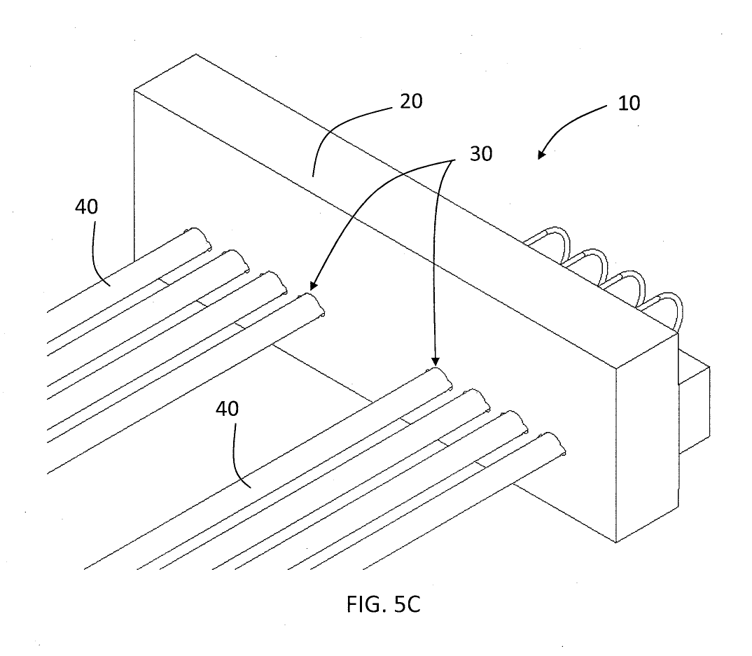

FIGS. 5A-5C schematically illustrate isometric views of an example optical system 10 including the optical fibers 40, the optical component 60, and the chip 100. FIGS. 5A and 5B show the first side 21 of the substrate 20 from two different angles with the optical component 60 and the chip 100 mounted thereon, and FIG. 5C shows the second side 22 of the substrate 20 with the optical fibers 40 within the holes 30. The optical component 60 (e.g., a surface-emitting laser array chip) can be placed upside down and attached to the substrate 20 using standard flip-chip bonding techniques. For example, the optical component 60 can comprise vertical-cavity surface-emitting lasers (VCSELs) with high frequency modulation capability for high speed data transmission (e.g., having an electrical bandwidth in, but not limited to, a range between 1 GHz to 25 GHz). The optical component 60 can be mounted on the first side 21 with its signal metal pads in electrical communication with the signal metal lines 61a. The optical component 60 can comprise a common ground metal plane 110 (e.g., on the backside of the optical component 60) that can be electrically connected to the ground metal lines 61b with a plurality of metal wires 112 (e.g., using standard wire bonding techniques). The other ends of the signal metal line 61a and the ground metal lines 61b can be connected to a laser driver circuit or chip which is used to supply electrical power and to modulate the laser output.

The surface-receiving photodetector array chip 100 can also be placed upside down and attached to the substrate 20 using the same standard flip-chip bonding techniques. For example, the photodetector array chip 100 can comprise high speed surface-receiving photodetectors (e.g., p-i-n photodiodes or metal-semiconductor-metal photoconductors). The electrical bandwidth of such photodetectors can be in, but is not limited to, a range between 1 GHz to 25 GHz. A signal metal line 103a and a ground metal line 103b can be formed on top of the substrate 20 at a location corresponding to each photodetector of the photodetector array chip 100. A signal metal pad and a ground metal pad of a photodetector of the photodetector array chip 100 can be electrically connected to the signal metal line 103a and the ground metal line 103b, respectively, during the flip-chip bonding process. The other end of the signal metal line 103a or the ground metal line 103b can be connected to a transimpedance amplifier (TIA) circuit or chip which is used to convert the photocurrent of the photodetector to voltage and amplify the voltage signal.

As schematically illustrated by FIG. 5C, a plurality of optical fibers 40 can be installed perpendicularly to the substrate 20 by being inserted into the array of holes 30 on the second side 22 of the substrate 20. The positions of the holes 30 and the fibers 40 can be aligned with the optical apertures 66 of the optical component 60 (e.g., the optical apertures of the lasers of a laser array chip) or with the optical apertures 101 of the photodetectors of the photodetector array chip 100.

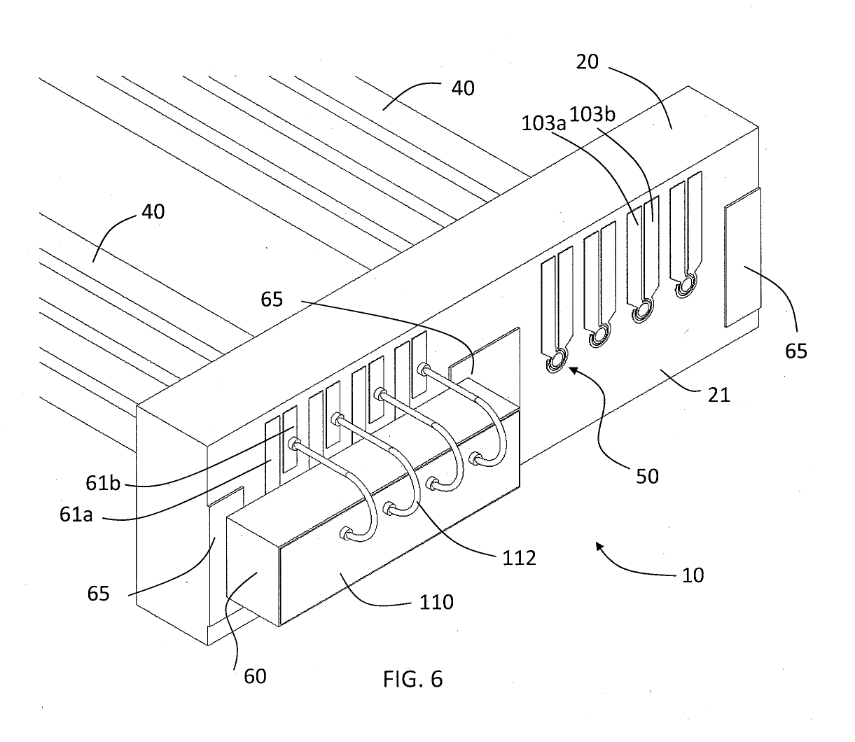

FIG. 6 schematically illustrates an isometric view of an example optical system 10 an array of monolithically integrated monitor photodetectors 50. Some of the photodetectors 50 are in optical communication with some of the optical fibers 40 and are configured to monitor the intensity of the optical signals emitted from these optical fibers 40. Some of the photodetectors 50 are in optical communication with some of the optical fibers 40 and the optical component 60, and are configured to monitor the intensity of the optical signals emitted from the optical component 60 towards the optical fibers 40. The integration of the photodetectors 50 in FIG. 6, as compared to the structure comprising the chip 100 (shown in FIGS. 5A-5B) can advantageously reduce the assembly complexity and cost and can advantageously save component costs (e.g., costs of the external photodetector array chips 100).

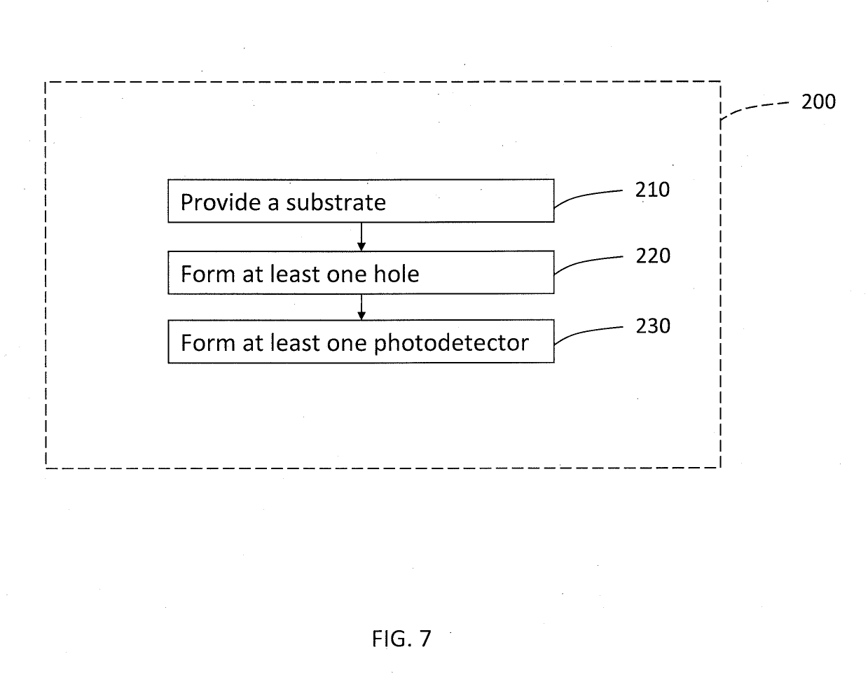

FIG. 7 is a flowchart of an example method 200 of fabricating an optical system 10 in accordance with the systems and methods described herein. In an operational block 210, the method 200 comprises providing a substrate 20 comprising a first side 21 and a second side 22 facing generally opposite to the first side 21. In an operational block 220, the method 200 further comprises forming at least one hole 30 extending from the second side 22 towards the first side 21. The at least one hole 30 is configured to receive at least one optical fiber 40. In an operational block 230, the method 200 further comprises forming at least one photodetector 50, wherein the at least one photodetector 50 is at the first side 2 or between the at least one hole 30 and the first side 21. The at least one photodetector 50 is configured to be in an optical path of an optical signal emitted from the at least one optical fiber 40 or transmitted through the first side 21 to the at least one optical fiber 40. The at least one photodetector 50 is responsive to the optical signal by generating an electrical signal indicative of an intensity of the optical signal.

Providing the substrate 20 in the operational block 210 can comprise providing a substrate 20 that includes a semiconductor material 23 over an etch stop layer 24 (e.g., by providing a SOI wafer), or providing the substrate 20 can comprise forming (e.g., depositing) one or both of the semiconductor material 23 and the etch stop layer 24. Forming the at least one hole 30 in the operational block 220 can comprise etching the substrate 20 from the second side 22 towards the first side 21, wherein the etching terminates at the etch stop layer 24. Forming the at least one photodetector 50 can comprise forming a light-responsive diode in the optical path, with the light-responsive diode comprising a p-doped semiconductor material and an n-doped semiconductor material which form a p-i-n diode or a p-n diode configured to generate an electric current in response to the optical signal. The various steps or processes of the operational blocks 210, 220, 230 of the method 200 can be sequential or interleaved with one another, and can be performed in various orders while still remaining compatible with the systems and methods described herein.

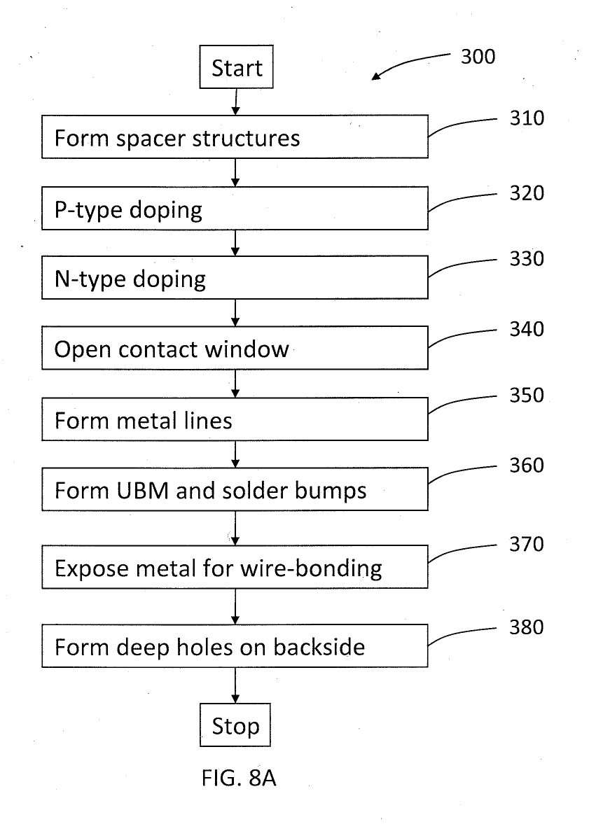

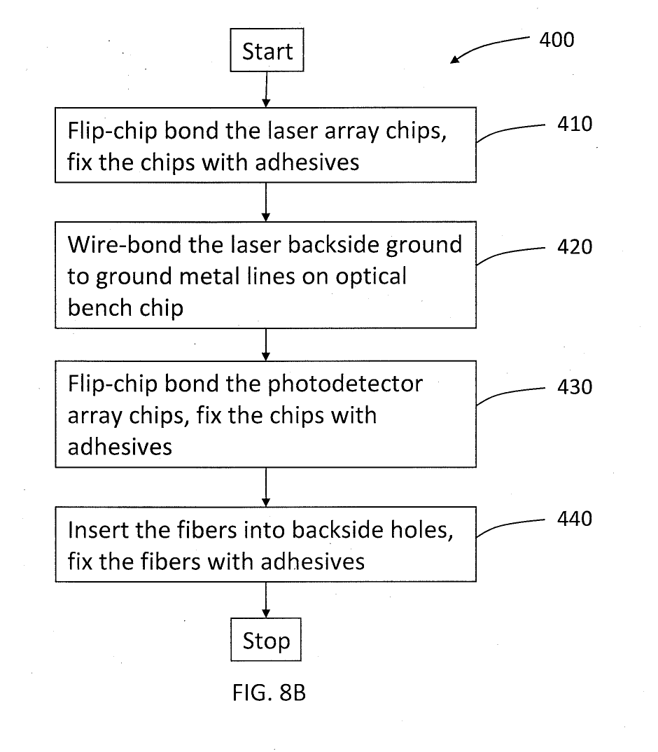

FIG. 8A illustrates an example process flow 300 of providing or fabricating an example substrate 20 as schematically illustrated by FIG. 4A. The operational blocks of the example process flow 300 can be part of the method 200 and of one or more of the operational blocks 210, 220, 230. All the structure patterns involved in each step of the example process flow of FIG. 8A can be defined by standard photolithography techniques. For example, based on the dimensions of the patterns in the process flow, any photolithography tools with 1 micron or better critical dimension resolution may be used. In an operational block 310, the spacer 65 can be formed (e.g., by using plasma or wet chemical to etch the patterned substrate material).

The method 300 can comprise forming the light-responsive diode which can comprise implanting p-type impurities into the semiconductor material 23 and implanting n-type impurities into the semiconductor material 23 (e.g., to form a light-responsive diode as schematically illustrated by FIG. 1B). For example, in operational blocks 320 and 330, selected regions of the semiconductor material 23 can be doped with p-type dopants and other selected regions (e.g., regions nearby or proximal to the p-doped regions) of the semiconductor material 23 can be doped with n-type dopants, to form p-i-n monitor photodetectors 50 having near-intrinsic regions between the p-doped and n-doped pairs of regions. Example doping techniques include, but are not limited to, ion-implantation and dopant diffusion. The order of the operational blocks 320 and 330 can be reversed from that shown in FIG. 8A. The implanted p-type impurities of the p-doped region 51 can extend a first depth into the semiconductor material 23 and the implanted n-type impurities of the n-doped region 52 can extend a second depth into the semiconductor material 23, with the first depth greater than the second depth or the first depth less than the second depth.

The method 300 can comprise forming the light-responsive diode which can comprise depositing the p-doped semiconductor material 51, depositing the n-doped semiconductor material 52, and depositing an active material of the region 54, wherein the active material is sandwiched between the p-doped semiconductor material and the n-doped semiconductor material (e.g., to form a light-responsive diode as schematically illustrated by FIG. 2B).

The method 300 can further comprise forming a plurality of metal traces on the first side 21 in electrical communication with the at least one photodetector 50, and forming a plurality of metal traces on the first side 21 configured to be flip-chip-bonded to at least one optical component 60 and to provide electrical communication to the at least one optical component 60. For example, in an operational block 340, an electrical insulative layer 62 can be deposited and can be etched from areas to form contact windows where the metal layers are to be deposited to provide electrical connection to the doped p-type and n-type regions. In an operational block 350, the metal layers can be deposited and etched to form metal lines which provide electrical connection to the p-i-n photodiode and metal layers 61 and metal solder bumps 64 to provide electrical connection to the optical component 60. In an operational block 360, a passivation layer can be deposited and a patterned under bump metallurgy (UBM) layer can be formed (if desired) with metal solder bumps 64. The patterned UBM layer can be formed by etching the UBM material, lifting off the material or plating the material. The solder bumps 64 can be formed by various techniques, including but not limited to plating and wedging. In an operational block 370, the passivation layer can be etched from areas where the underlying metal lines are desired to be exposed for wire-bonding. In an operational block 380, the holes 30 can be etched from the second side 22 of the substrate 20. The process can also include a front-side-backside alignment during the photolithography patterning to have the structures appropriately aligned.

FIG. 8B illustrates an example process flow 400 of assembling the example optical system 10 of FIG. 5A. The operational blocks of the example process flow 400 can be part of the method 200 and of one or more of the operational blocks 210, 220, 230. In an operational block 410, the optical component 60 can be aligned and flip-chip bonded onto the substrate 20, which can include fixing the optical component 60 by applying adhesive from the sides. In an operational block 420, the backside ground metal 110 of the optical component 60 can be wire-bonded to the ground metal lines on the substrate 20. In an operational block 430, the photodetector array chip 100 can be aligned and flip-chip bonded onto the substrate 20, which can include fixing the photodetector array chip 100 by applying adhesive from the sides. In an operational block 440, the optical fibers 40 can be inserted into the holes 30 from the second side 22 of the substrate 20, which can include fixing the optical fibers 40 by applying adhesive into the extended portions 107 of the holes 30.

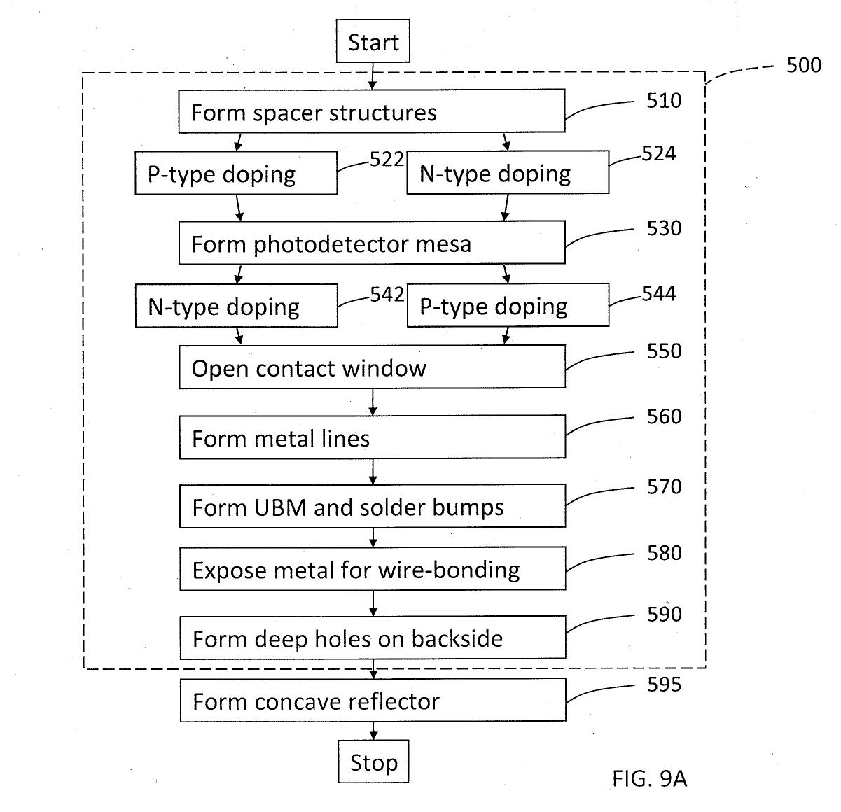

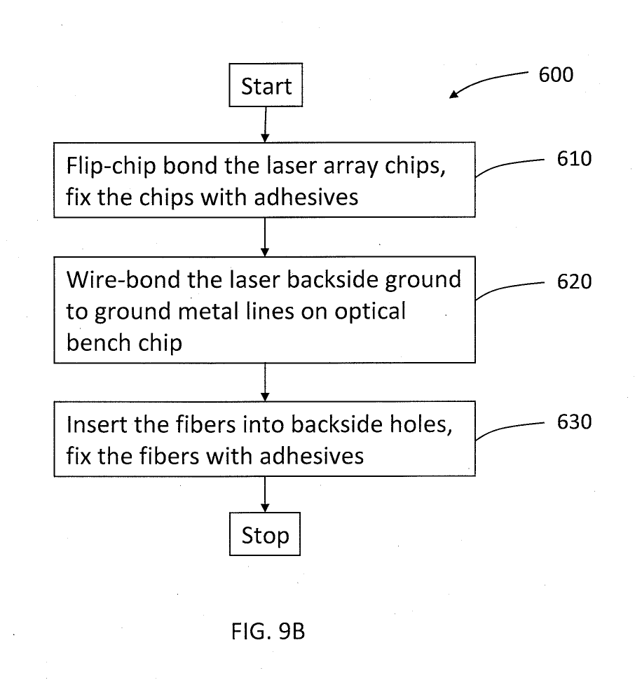

FIG. 9A illustrates an example process flow 500 of providing or fabricating an example substrate 20 as schematically illustrated by FIG. 6. The operational blocks of the example process flow 500 can be part of the method 200 and of one or more of the operational blocks 210, 220, 230. The example process flow 500 has some similarity with the example process flow 300 of FIG. 8A as described above. For example, forming the spacers 65 in the operational block 510 can be performed (e.g., by using plasma or wet chemical to etch the patterned substrate material), as disclosed above in the description of operational block 310, and opening a contact window, forming metal lines, forming UBM and solder bumps, exposing metal for wire-bonding, and forming holes from the second side in operational blocks 550, 560, 570, 580, and 590, respectively, can be performed as disclosed above in the description of operational blocks 340, 350, 360, 370, and 380, respectively.

The example process flow 500 can comprise two alternative process flows in which the sequence of p-type doping and n-type doping may be swapped. For example, the example process flow 500 can comprise forming a p-doped region (e.g., by p-type doping of the semiconductor material 23) in an operational block 522, forming a photodetector mesa (e.g., depositing the active material of the region 54 over the p-doped region) in an operational block 530, and forming an n-doped region (e.g., by depositing an n-doped layer over the active material of the region 54). Alternatively, the example process flow 500 can comprise forming an n-doped region (e.g., by n-type doping of the semiconductor material 23) in an operational block 524, forming a photodetector mesa (e.g., depositing the active material of the region 54 over the n-doped region) in an operational block 530, and forming a p-doped region (e.g., by depositing a p-doped layer over the active material of the region 54).

In the operational block 530, the region 54 can be in the form of a mesa comprising an optical absorption material. For example, the absorption material can be deposited or grown on top of the first side 21 (e.g., over the underlying doped region of the substrate 20), then defined by photolithography and etching processes, or it can be grown selectively in the mesa areas which are defined by patterned growth windows.

In processes in which both monitor photodetectors 50 (e.g., between optical fibers 40 and optical components 60 as in FIG. 1B) and signal photodetectors 50 (e.g., above optical fibers 40 as in FIG. 2B) are being formed concurrently, the p-type doping of operational block 522 and/or the n-type doping of operational block 524 can be applied to the appropriate regions (e.g., to one or both of the p-doped regions 51 and the n-doped regions of the semiconductor material 23 as shown in FIGS. 1B and 2B). In processes in which both monitor photodetectors 50 (e.g., between optical fibers 40 and optical components 60 as in FIG. 1B) and signal photodetectors 50 (e.g., above optical fibers 40 as in FIG. 2B) are being formed concurrently, the n-type doping of operational block 542 and/or the p-type doping of operational block 544 can be applied to the appropriate regions (e.g., to one or both of the p-doped regions 51 and the n-doped regions of the semiconductor material 23 or the region 54 as shown in FIGS. 1B and 2B).

The example process flow 500 can further comprise forming at least one concave reflective element 80 on the first side 21 in an operational block 595. As schematically illustrated by FIG. 2C, the at least one concave reflective element 80 can be configured to reflect at least a portion of the optical signal emitted from the at least one optical fiber 40 back to the at least one photodetector 50. Example processes and materials for forming the reflective element 80 in the operational block 595 are disclosed above with respect to the structure schematically illustrated in FIG. 2C.

FIG. 9B illustrates an example process flow 600 of assembling the example optical system 10 of FIG. 6. The operational blocks of the example process flow 600 can be part of the method 200 and of one or more of the operational blocks 210, 220, 230. In an operational block 610, the optical component 60 (e.g., laser array chip) can be aligned and flip-chip bonded onto the substrate 20, which can include fixing the optical component 60 by applying adhesive from the sides. The flip-chip-mounting of the at least one optical component 60 on the first side 21 can be performed such that the at least one optical component 60 is in optical communication with the at least one optical fiber 40 and the at least one photodetector 50 is between the at least one optical component 60 and the at least one optical fiber 40. In an operational block 620, the backside ground metal 110 of the optical component 60 can be wire-bonded to the ground metal lines on the substrate 20. In an operational block 630, the optical fibers 40 can be inserted into the holes 30 from the second side 22 of the substrate 20, which can include fixing the optical fibers 40 by applying adhesive into the extended portions 107 of the holes 30. Inserting the at least one optical fiber 40 into the at least one hole 30 can be performed such that the at least one optical fiber 40 is in optical communication with the at least one photodetector 50.

For configurations in which a ball lens 90 is to be used (e.g., as schematically illustrated by FIG. 2D), the process flow 600 can comprise inserting at least one ball lens 90 within the at least one hole 30, with the at least one ball lens 90 between the at least one optical fiber 40 and the at least one photodetector 50. The ball lens 90 can be inserted into the hole 30 before inserting the optical fiber 40. In configurations in which the width or diameter of the ball lens 90 is the same as the width or diameter of the fiber 40, the ball lens 90 can be tightly fit inside the hole 30, which has a width or diameter which is slightly larger than that of the ball lens 90 or optical fiber 40, as described above.

Various embodiments of the present invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

What is claimed is:

1. An optical system comprising:
a substrate comprising a first side and a second side facing generally opposite to the first side; and
at least one hole extending from the second side towards the first side, the at least one hole configured to receive at least one optical fiber,
wherein the substrate comprises at least one photodetector at the first side or between the at least one hole and the first side, wherein the at least one photodetector is configured to be in an optical path of an optical signal emitted from the at least one optical fiber or transmitted through the first side to the at least one optical fiber, the at least one photodetector responsive to the optical signal by generating an electrical signal indicative of an intensity of the optical signal.

2. The optical system of claim 1, wherein the at least one photodetector comprises a semiconductor material in the optical path.

3. The optical system of claim 2, wherein the substrate comprises an etch stop layer between the at least one hole and the semiconductor material.

4. The optical system of claim 3, wherein the semiconductor material comprises crystalline silicon or polysilicon, and the etch stop layer comprises silicon oxide.

5. The optical system of claim 2, wherein the substrate comprises gallium arsenide and the semiconductor material comprises lattice-matched gallium indium phosphide on the gallium arsenide.

6. The optical system of claim 2, wherein the substrate comprises indium phosphide and the semiconductor material comprises lattice-matched indium gallium arsenide on the indium phosphide.

7. The optical system of claim 1, wherein the at least one photodetector comprises a light-responsive diode in the optical path.

8. The optical system of claim 7, wherein the light-responsive diode comprises a p-i-n diode or a p-n diode configured to generate an electric current in response to the optical signal.

9. The optical system of claim 7, wherein the light-responsive diode comprises a p-doped region, an n-doped region, and a region sandwiched between the p-doped region and the n-doped region.

10. The optical system of claim 1, wherein the substrate further comprises at least one metal layer at the first side, the at least one metal layer configured to be in electrical communication with at least one optical component mounted on the first side.

11. The optical system of claim 10, wherein the substrate further comprises at least one electrically insulative layer between the at least one metal layer and the at least one hole.

12. An optical system comprising:
a substrate comprising a first side and a second side facing generally opposite to the first side;
at least one hole extending from the second side towards the first side;
at least one optical fiber mounted to the substrate with a portion of the at least one optical fiber within the at least one hole,
wherein the substrate comprises at least one photodetector at the first side or between the at least one optical fiber and the first side, wherein the at least one photodetector is configured to be in an optical path of an optical signal emitted from the at least one optical fiber or transmitted through the first side to the at least one optical fiber, the at least one photodetector responsive to the optical signal by generating an electrical signal indicative of an intensity of the optical signal.

13. The optical system of claim 12, wherein the at least one hole comprises an array of holes, the at least one optical fiber comprises an array of optical fibers, and the at least one photodetector comprises an array of photodetectors.

14. The optical system of claim 12, further comprising at least one optical component mounted on the first side, the at least one optical component in optical communication with the at least one optical fiber, wherein the optical path extends through the first side and between the at least one optical component and the at least one optical fiber.

15. The optical system of claim 14, wherein the at least one optical component comprises a surface emitting light source.

16. The optical system of claim 14, wherein the substrate further comprises a plurality of metal traces at the first side, the plurality of metal traces configured to be flip-chip-bonded to the at least one optical component and to provide electrical communication to the at least one optical component.

17. The optical system of claim 16, wherein the substrate further comprises at least one electrically insulative layer between the plurality of metal traces and the at least one hole.

18. The optical system of claim 12, wherein the substrate further comprises a plurality of metal traces at the first side, the plurality of metal traces in electrical communication with the at least one photodetector.

19. The optical system of claim 12, further comprising at least one concave reflective element on the first side, the at least one concave reflective element configured to reflect at least a portion of the optical signal emitted from the at least one optical fiber back to the at least one photodetector.

20. The optical system of claim 12, further comprising at least one ball lens within the at least one hole and between the at least one optical fiber and the at least one photodetector.

21. A method of fabricating an optical system, the method comprising:
providing a substrate comprising a first side and a second side facing generally opposite to the first side;
forming at least one hole extending from the second side towards the first side, the at least one hole configured to receive at least one optical fiber; and
forming at least one photodetector, wherein the at least one photodetector is at the first side or between the at least one hole and the first side, wherein the at least one photodetector is configured to be in an optical path of an optical signal emitted from the at least one optical fiber or transmitted through the first side to the at least one optical fiber, the at least one photodetector responsive to the optical signal by generating an electrical signal indicative of an intensity of the optical signal.

22. The method of claim 21, wherein the substrate comprises an etch stop layer between the first side and the second side, and forming the at least one hole comprises etching the substrate from the second side towards the first side, wherein the etching terminates at the etch stop layer.

23. The method of claim 21, wherein forming the at least one photodetector comprises forming a light-responsive diode in the optical path, the light-responsive diode comprising a p-doped semiconductor material and an n-doped semiconductor material, the p-doped semiconductor material and the n-doped semiconductor material forming a p-i-n diode or a p-n diode configured to generate an electric current in response to the optical signal.

24. The method of claim 23, wherein forming the light-responsive diode comprises:
depositing the p-doped semiconductor material;
depositing the n-doped semiconductor material; and
depositing an active material, wherein the active material is sandwiched between the p-doped semiconductor material and the n-doped semiconductor material.

25. The method of claim 23, wherein the substrate comprises a semiconductor material at the first side or between the at least one hole and the first side, and forming the light-responsive diode comprises implanting p-type impurities into the semiconductor material and implanting n-type impurities into the semiconductor material.

26. The method of claim 25, wherein the implanted p-type impurities extend a first depth into the semiconductor material and the implanted n-type impurities extend a second depth into the semiconductor material, the first depth greater than the second depth.

27. The method of claim 25, wherein the implanted p-type impurities extend a first depth into the semiconductor material and the implanted n-type impurities extend a second depth into the semiconductor material, the first depth less than the second depth.

28. The method of claim 21, further comprising forming a plurality of metal traces on the first side, the plurality of metal traces configured to be flip-chip-bonded to at least one optical component and to provide electrical communication to the at least one optical component.

29. The method of claim 21, further comprising forming a plurality of metal traces on the first side, the plurality of metal traces in electrical communication with the at least one photodetector.

30. The method of claim 21, further comprising forming at least one concave reflective element on the first side, the at least one concave reflective element configured to reflect at least a portion of the optical signal emitted from the at least one optical fiber back to the at least one photodetector.

31. A method of fabricating an optical system, the method comprising:
providing a substrate comprising:
a first side and a second side facing generally opposite to the first side;
at least one hole extending from the second side towards the first side; and
at least one photodetector at the first side or between the at least one hole and the first side; and
inserting at least one optical fiber into the at least one hole, wherein the at least one optical fiber is in optical communication with the at least one photodetector.

32. The method of claim 31, further comprising flip-chip-mounting at least one optical component on the first side such that the at least one optical component is in optical communication with the at least one optical fiber and the at least one photodetector is between the at least one optical component and the at least one optical fiber.

33. The method of claim 31, further comprising inserting at least one ball lens within the at least one hole, wherein the at least one ball lens is between the at least one optical fiber and the at least one photodetector.
